(19) United States
(12) Patent Application Publication
(10) Pub. No.: US 2019/0279997 A1
(43) Pub. Date: Sep. 12, 2019

(54) SEMICONDUCTOR DEVICE AND MANUFACTURING METHOD OF SEMICONDUCTOR DEVICE

(71) Applicant: Toshiba Memory Corporation, Minato-ku (JP)

(72) Inventors: Kouta NISHIMORI, Suzuka (JP); Kazuma TAKAHASHI, Kuwana (JP); Hisakazu MATSUMORI, Yokkaichi (JP)

(73) Assignee: Toshiba Memory Corporation, Minato-ku (JP)

(21) Appl. No.: 16/111,388

(22) Filed: Aug. 24, 2018

(30) Foreign Application Priority Data
Mar. 6, 2018 (JP) 2018-039571

(51) Int. Cl. H01L 27/11573; H01L 27/11524; H01L 27/11556; H01L 27/11529; H01L 27/1157; H01L 27/11582; H01L 29/49; H01L 23/535; H01L 21/768; H01L 21/28

(52) U.S. Cl. CPC H01L 27/11573; H01L 27/11524; H01L 27/11556; H01L 27/11529; H01L 27/1157; H01L 21/28035; H01L 29/4916; H01L 23/535; H01L 21/76805; H01L 21/76895; H01L 27/11582

(57) ABSTRACT

According to one embodiment, a semiconductor device includes: a first transistor including a first stack in which a first oxide, a first nitride, a first conductor, and a second nitride are subsequently stacked; and first regions bracketing the first stack; and a second transistor including a second stack in which a second oxide, a second conductor, and a third nitride are subsequently stacked; and second regions bracketing the second stack, wherein the first transistor further includes a third oxide provided on the first regions and a fourth nitride consecutively provided on the third oxide and the second nitride, and the second transistor further includes a fourth oxide consecutively provided on the second regions and the third nitride, and a fifth nitride provided on the fourth oxide.

### CROSS-REFERENCE TO RELATED APPLICATIONS

This application is based upon and claims the benefit of priority from Japanese Patent Application No. 2018-039571, filed Mar. 6, 2018, the entire contents of which are incorporated herein by reference.

### FIELD

Embodiments described herein relate generally to a semiconductor device and a manufacturing method of the semiconductor device.

### BACKGROUND

A NAND-type flash memory in which memory cells are stacked three-dimensionally is known.

### BRIEF DESCRIPTION OF THE DRAWINGS

FIG. 1 is a block diagram for explaining a configuration of a semiconductor memory according to a first embodiment.

FIG. 2 is a circuit diagram for explaining a configuration of a memory cell array of the semiconductor memory according to the first embodiment.

FIG. 3 is a cross-sectional view for explaining a configuration of a NAND string of the semiconductor memory according to the first embodiment.

FIG. 4 is a cross-sectional view for explaining a configuration of a memory area, a hook-up area, and a peripheral area of the semiconductor memory according to the first embodiment.

FIG. 5 is a cross-sectional view for explaining a configuration of a p-type transistor formed in the peripheral area of the semiconductor memory according to the first embodiment.

FIG. 6 is a cross-sectional view for explaining a configuration of a p-type transistor formed in the peripheral area of the semiconductor memory according to the first embodiment.

FIG. 7 is a cross-sectional view for explaining a configuration of an n-type transistor formed in the peripheral area of the semiconductor memory according to the first embodiment.

FIG. 8 is a cross-sectional view for explaining a manufacturing method of transistors of the semiconductor memory according to the first embodiment.

FIG. 9 is a cross-sectional view for explaining a manufacturing method of the transistors of the semiconductor memory according to the first embodiment.

FIG. 10 is a cross-sectional view for explaining a manufacturing method of the transistors of the semiconductor memory according to the first embodiment.

FIG. 11 is a cross-sectional view for explaining a manufacturing method of the transistors of the semiconductor memory according to the first embodiment.

FIG. 12 is a cross-sectional view for explaining a manufacturing method of the transistors of the semiconductor memory according to the first embodiment.

FIG. 13 is a cross-sectional view for explaining a manufacturing method of the transistors of the semiconductor memory according to the first embodiment.

FIG. 14 is a cross-sectional view for explaining a manufacturing method of a semiconductor memory according to the first embodiment.

FIG. 15 is a cross-sectional view for explaining a manufacturing method of the semiconductor memory according to the first embodiment.

FIG. 16 is a cross-sectional view for explaining a manufacturing method of the semiconductor memory according to the first embodiment.

FIG. 17 is a cross-sectional view for explaining a manufacturing method of the semiconductor memory according to the first embodiment.

FIG. 18 is a cross-sectional view for explaining a manufacturing method of the semiconductor memory according to the first embodiment.

FIG. 19 is a cross-sectional view for explaining a manufacturing method of the semiconductor memory according to the first embodiment.

FIG. 20 is a cross-sectional view for explaining a manufacturing method of the semiconductor memory according to the first embodiment.

FIG. 21 is a cross-sectional view for explaining a manufacturing method of the semiconductor memory according to the first embodiment.

FIG. 22 is a cross-sectional view for explaining a manufacturing method of the semiconductor memory according to the first embodiment.

FIG. 23 is a cross-sectional view for explaining a manufacturing method of the semiconductor memory according to the first embodiment.

FIG. 24 is a cross-sectional view for explaining a manufacturing method of the semiconductor memory according to the first embodiment.

FIG. 25 is a schematic diagram for explaining advantageous effects according to the first embodiment.

FIG. 26 is a cross-sectional view for explaining a configuration of a p-type transistor formed in a peripheral area of a semiconductor memory according to a second embodiment.

FIG. 27 is a cross-sectional view for explaining a configuration of a p-type transistor formed in the peripheral area of the semiconductor memory according to the second embodiment.

FIG. 28 is a cross-sectional view for explaining a configuration of an n-type transistor formed in the peripheral area of the semiconductor memory according to the second embodiment.

FIG. 29 is a cross-sectional view for explaining a manufacturing method of transistors of the semiconductor memory according to the second embodiment.

FIG. 30 is a cross-sectional view for explaining a manufacturing method of the transistors of the semiconductor memory according to the second embodiment.

FIG. 31 is a cross-sectional view for explaining a manufacturing method of the transistors of the semiconductor memory according to the second embodiment.

FIG. 32 is a cross-sectional view for explaining a manufacturing method of the transistors of the semiconductor memory according to the second embodiment.

FIG. 33 is a cross-sectional view for explaining a manufacturing method of the transistors of the semiconductor memory according to the second embodiment.

FIG. 34 is a cross-sectional view for explaining a manufacturing method of the transistors of the semiconductor memory according to the second embodiment.

FIG. 35 is a cross-sectional view for explaining a manufacturing method of the transistors of the semiconductor memory according to the second embodiment.

FIG. 36 is a cross-sectional view for explaining a manufacturing method of the transistors of the semiconductor memory according to the second embodiment.

### DETAILED DESCRIPTION

In general, according to one embodiment, a semiconductor device includes: a first transistor that includes: a first stacked body in which a first oxide, a first nitride, a first conductor, and a second nitride are subsequently stacked above a substrate; and first diffusion regions that are provided on the substrate and bracket the first stacked body; and a second transistor that includes: a second stacked body in which a second oxide, a second conductor, and a third nitride are subsequently stacked above the substrate; and second diffusion regions that are provided on the substrate and bracket the second stacked body, wherein the first transistor further includes: a third oxide provided on the first diffusion regions, and a fourth nitride consecutively provided on the third oxide and the second nitride, and wherein the second transistor further includes: a fourth oxide consecutively provided on the second diffusion regions and the third nitride, and a fifth nitride provided on the fourth oxide.

Hereinafter, the embodiment will be described with reference to the accompanying drawings. The drawings are schematic. Each embodiment is an example of an apparatus or a method to embody the technical idea of the invention. In the explanation that follows, constituent elements having the same functions and configurations will be denoted by the same reference symbols. The numbers after the letters constituting the reference symbols are used to discriminate elements which are denoted by the reference symbols that include the same letters and which have similar configurations. If there is no need of mutually distinguishing the elements which are denoted by the reference symbols that include the same letters, the same elements are denoted by the reference symbols that include only the same letters.

### 1. First Embodiment

A semiconductor memory according to the first embodiment will be described.

### 1.1 Configuration

1.1.1 Configuration of Semiconductor Memory

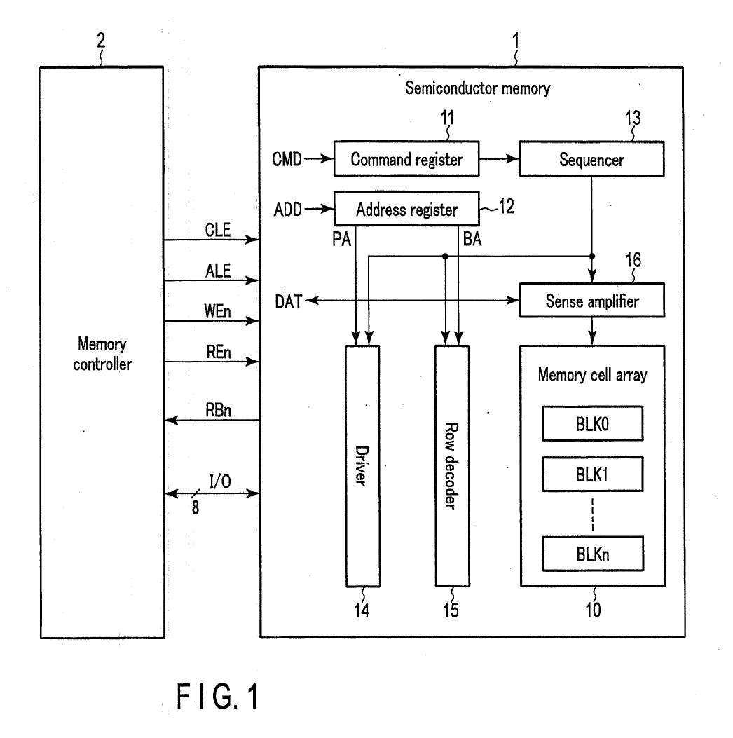

FIG. 1 is a block diagram for explaining the configuration of a semiconductor memory according to the first embodiment. As shown in FIG. 1, a semiconductor memory 1 is a NAND-type flash memory that is capable of storing data in a non-volatile manner, for example. The semiconductor memory 1 includes, for example, a memory cell array 10, a command register 11, an address register 12, a sequencer 13, a driver 14, a row decoder 15, and a sense amplifier 16.

The memory cell array 10 includes a plurality of blocks BLK0 to BLKn (“n” is an integer equal to or greater than 1). A block BLK is a set of non-volatile memory cells, and is, for example, a unit of data erasure. In the memory cell array 10, a plurality of bit lines and a plurality of word lines are provided, and each memory cell is associated with one bit line and one word line. The configuration of the memory cell array 10 will be described later in detail.

The command register 11 retains a command CMD that is received by the semiconductor memory 1 from an external memory controller 2. The command CMD includes instructions to cause the sequencer 13 to execute a read operation and a write operation, for example.

The address register 12 retains address information ADD that is received by the semiconductor memory 1 from the memory controller 2. The address information ADD includes, for example, a block address BA and a page address PA. The block address BA is used to select a block BLK that includes a memory cell targeted for various types of operations. The page address PA is used to select a word line associated with a memory cell targeted for various types of operations.

The sequencer 13 controls the operation of the entire semiconductor memory 1 based on the command CMD retained in the command register 11. For example, the sequencer 13 controls the driver 14, the row decoder 15, and the sense amplifier 16 to perform a write operation for data DAT received from the memory controller 2.

The driver 14 generates a desired voltage under control of the sequencer 13. Subsequently, the driver 14 respectively applies, to corresponding signal lines, a voltage to be applied to a word line that is selected, for example, based on the page address PA retained in the address register 12, and a voltage to be applied to word lines that are not selected.

The row decoder 15 selects one block BLK based on the block address BA retained in the address register 12. The row decoder 15 thereafter applies the voltage applied to each signal line by the driver 14 to each of the selected word line and the unselected word lines, for example.

The sense amplifier 16 applies a desired voltage to each bit line in accordance with write data DAT received from the memory controller 2. The sense amplifier 16 determines data stored in a memory cell based on the voltage of the bit line, and transmits the determined read data DAT to the memory controller 2.

In the communications between the semiconductor memory 1 and the memory controller 2, the NAND interface standards, for example, are supported. For example, the memory controller 2 transmits a command latch enable signal CLE, an address latch enable signal ALE, a write enable signal WEn, and a read enable signal REn; receives a ready/busy signal REn; and transmits and receives an input/output signal I/O. The signal CLE is a signal notifying the semiconductor memory 1 that the received signal I/O is a command CMD. The signal ALE is a signal notifying the semiconductor memory 1 that the received signal I/O is address information ADD. The signal WEn is a signal instructing the semiconductor memory 1 to input the signal I/O. The signal REn is a signal instructing the semiconductor memory 1 to output the signal I/O. The signal RBn is a signal for notifying the memory controller 2 of whether the semiconductor memory 1 is in a ready state in which an instruction from the memory controller 2 can be received, or in a busy state in which an instruction from the memory controller 2 cannot be received. The signal I/O is, for example, an 8-bit signal, and may include a command CMD, address information ADD, write data DAT, and read data DAT, etc.

The semiconductor memory 1 and the memory controller 2 as described in the above may constitute one semiconductor device by a combination thereof. Examples of such a semiconductor device may include a memory card, such as an SD™ card, a solid state drive (SSD), etc.

1.1.2 Circuit Configuration of Memory Cell Array

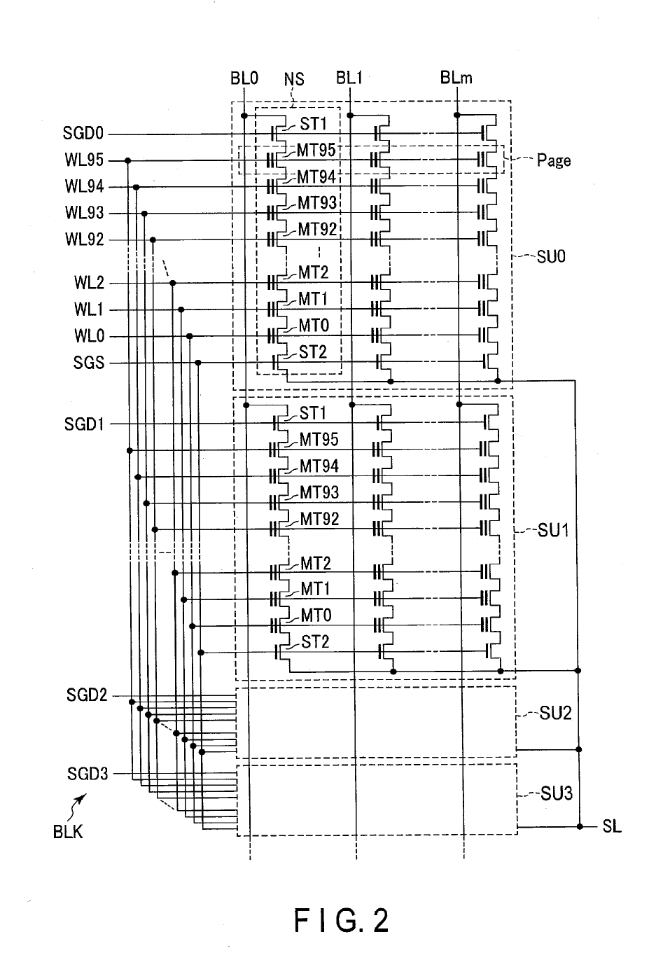

FIG. 2 shows an example of a circuit configuration of the memory cell array 10 according to the first embodiment. The circuit configuration of the memory cell array 10 according to the first embodiment will be described below, focusing on one block BLK.

A block BLK includes, for example, four string units, SU0 to SU3, as shown in FIG. 2 as an example. Each string unit SU includes a plurality of NAND strings NS that are respectively associated with the bit lines BL0 to BLm (“m” is an integer equal to or greater than 1). A NAND string NS includes, for example, 96 memory cell transistors MT0 to MT95 and selection transistors ST1 and ST2.

Each memory cell transistor MT is provided with a control gate and a charge storage layer, and stores data in a nonvolatile manner. Memory cell transistors MT0 to MT95 included in each NAND string NS are coupled in series between a source of the selection transistor ST1 and a drain of the selection transistor ST2. The control gates of the memory cell transistors MT0 to MT95 in the same block BLK are respectively coupled in common to the word lines WL0 to WL95 in common. A set of one-bit data that is stored in the plurality of memory cell transistors MT coupled in common to a word line WL in each string unit SU is referred to as a “page”.

The selection transistors ST1 and ST2 are used to select a string unit SU at the time of various types of processing. The gates of selection transistors ST1 in the string units SU0 to SU3 in the same block BLK are respectively coupled in common to the selection gate lines SGD0 to SGD3. The drains of selection transistors ST1 in the same column in each block BLK are coupled in common to the corresponding bit line BL. The gates of selection transistors ST2 in the same block BLK are coupled in common to a selection gate line SGS. The sources of selection transistors ST2 in each block BLK are coupled in common to a source line SL between multiple blocks BLK.

The circuit configuration of the memory cell array 10 is not limited thereto. For example, the number of string units SU included in each block BLK and the number of memory cell transistors MT and selection transistors ST1 and selection transistors ST2 included in each NAND string NS may be discretionarily changed. The number of word lines WL and the number of selection gate lines SGD and SGS can be changed based on the number of memory cell transistors MT and the number of selection transistors ST1 and selection transistors ST2.

1.1.3 Configuration of Memory Cell Array

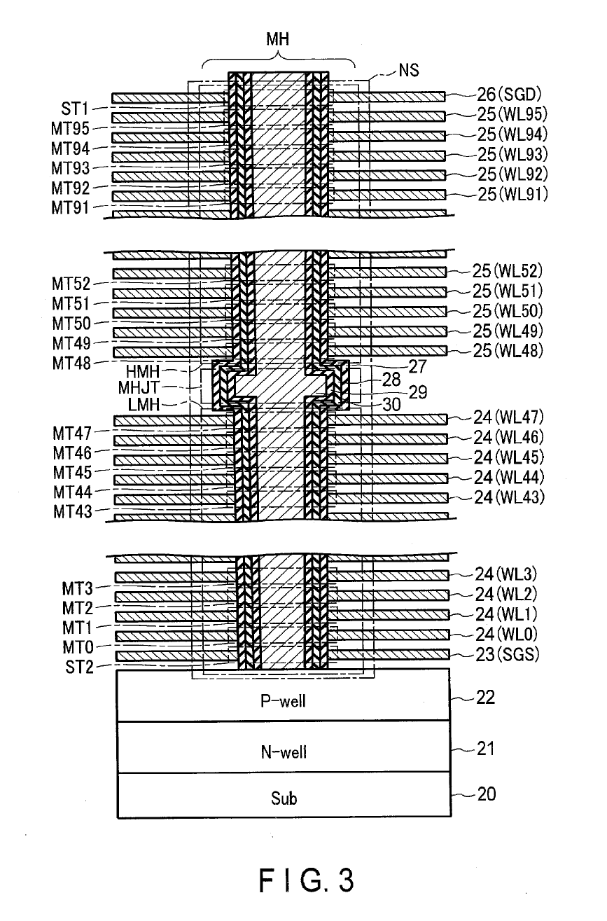

FIG. 3 is a cross-sectional view for explaining the configuration of the memory cell array of the semiconductor memory according to the first embodiment. Specifically, FIG. 3 illustrates an example cross-sectional view of a NAND string NS in a block BLK. In FIG. 3, some insulators (interlayer insulation films) provided between word lines WL are properly omitted.

As shown in FIG. 3, an n-type well region 21 is formed on a semiconductor substrate 20, and a p-type well region 22 is formed on n-type well region 21. Conductors 23 through 26 are sequentially provided above p-type well region 22, with an insulator being interposed therebetween. Conductors 23 through 26 are formed in a plate shape expanding along a plane parallel to the surface of the semiconductor substrate 20. Conductors 23 through 26 respectively function as the selection gate line SGS, the word lines WL0 to WL47, the word lines WL48 to WL95, and the selection gate line SGD.

A semiconductor pillar MH is provided from above a conductor 26 to penetrate conductors 23-26 to reach p-type well region 22. The semiconductor pillar MH includes, for example, a block insulation film 27, an insulation film 28, a tunnel oxide film 29, and a conductive semiconductor film 30. The block insulation film 27 is provided on an inner wall of a memory hole forming the semiconductor pillar MH, an insulation film 28 is provided on an inner wall of the block insulation film 27, the tunnel oxide film 29 is provided on an inner wall of the insulation film 28, and the semiconductor film 30 is embedded inside of the tunnel oxide film 29. A film of a different material may be additionally formed inside of the semiconductor film 30.

The semiconductor pillar MH includes a lower layer semiconductor pillar LMH, a higher layer semiconductor pillar HMH, and a semiconductor pillar junction MHJT. The lower layer semiconductor pillar LMH and the higher layer semiconductor pillar HMH are arranged at a lower position of the semiconductor pillar junction MHJT and at a higher position of the semiconductor pillar junction MHJT, respectively. Specifically, the lower layer semiconductor pillar LMH is provided on a lower surface of the semiconductor pillar junction MHJT to reach the upper surface of p-type well region 22. The higher layer semiconductor pillar HMH is provided from above conductor 26 to reach an upper surface of the semiconductor pillar junction MHJT.

On a junction surface between the semiconductor pillar junction MHJT and the lower layer semiconductor pillar LMH, the diameter of the semiconductor film 30 on the lower surface of the semiconductor pillar junction MHJT is greater than the diameter of the semiconductor film 30 on an upper surface of the lower layer semiconductor pillar LMH. On a junction surface between the semiconductor pillar junction MHJT and the higher layer semiconductor pillar HMH, the diameter of the semiconductor film 30 on the upper surface of the semiconductor pillar junction MHJT is greater than the diameter of the semiconductor film 30 on a lower surface of the higher layer semiconductor pillar HMH.

In the above-described configuration of the semiconductor pillar MH, the insulation film 28 functions as a charge storage layer of memory cell transistors MT, and a channel of the NAND string NS is formed in the semiconductor film 30. Portion in which the semiconductor pillar MH crosses conductor 23 function as selection transistor ST2; portions in which the semiconductor pillar MH crosses conductors 24 that function as word lines WL0 through WL47 function as memory cell transistors MT0 through MT47; portions in which the semiconductor pillar MH crosses conductors 25 that function as word lines WL48 through WL95 function as memory cell transistors MT48 through MT95; and portion in which the semiconductor pillar MH crosses conductor 26 function as selection transistor ST1.

The above-described configuration shown in FIG. 3 is merely an example, and other configurations may be suitably adopted. For example, a conductor (not shown in the drawings) that functions as a source line SL may be further provided between the semiconductor substrate 20 and conductors 23 shown in FIG. 3. In addition, a stacked structure (not shown in the drawings) which forms a peripheral circuit that functions as the row decoder 15 or the sense amplifier 16 may be further provided between the conductor and the semiconductor substrate 20.

1.1.4 Peripheral Configuration of Memory Cell Array

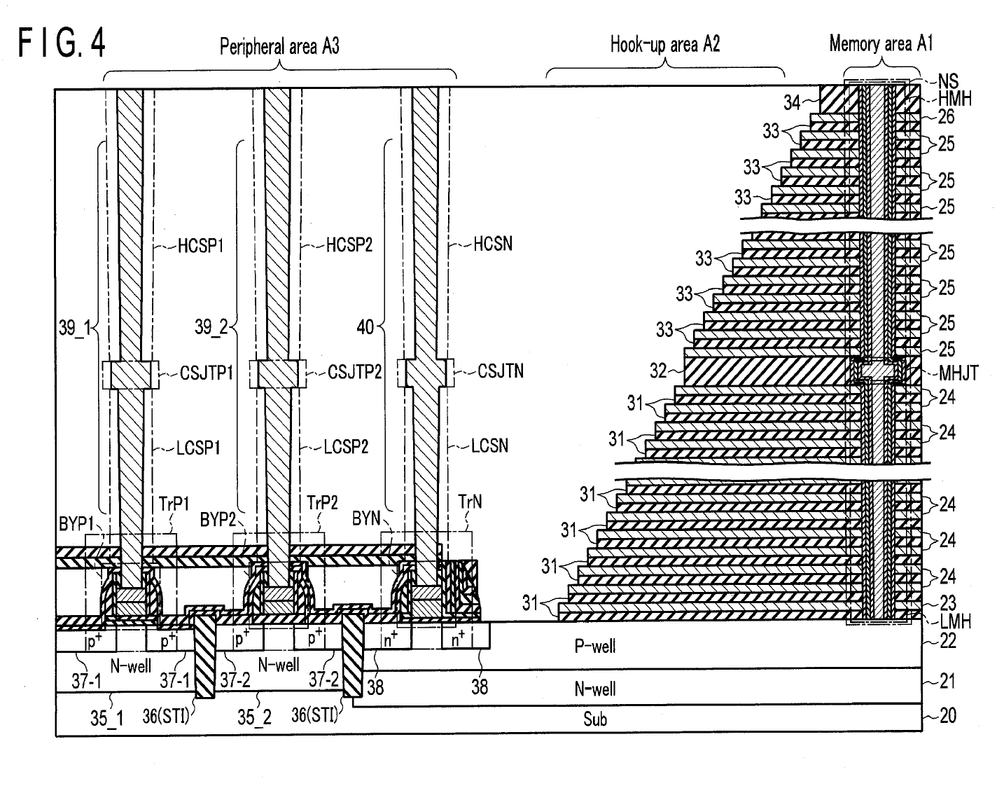

The peripheral configuration of the memory cell array of the semiconductor memory according to the first embodiment will be described. FIG. 4 is a cross-sectional view for explaining the configuration of a peripheral area of the semiconductor memory according to the first embodiment.

FIG. 4 illustrates a memory area A1, a hook-up area A2 and a peripheral area A3. The memory area A1, and the hook-up area A2 are formed by a stacked structure of conductors 23-26 and insulators 31-34. Specifically, the memory area A1 is an area of the stacked structure in which the NAND string NS described with reference to FIG. 3 is formed. The hook-up area A2 is an area where conductors 23-26 and insulators 31-34 extending from the memory area A1 are formed in a stepwise manner. The peripheral area A3 is an area peripheral to the memory area A1 and the hook-up area A2 where peripheral circuits of the memory cell array 10 that form, for example, the row decoder 15, the sense amplifier 16, etc. are formed.

As shown in FIG. 4, in the memory area A1 and the hook-up area A2, each of insulators 31 is provided between p-type well region 22 and conductor 23, and between respective layers of conductors 23 and 24. Layers in which insulators 31 and conductors 23 and 24 are provided correspond to layers in which the lower layer semiconductor pillar LMH of the NAND string NS is formed. Insulator 32 is provided between conductor 24 at the uppermost layer and conductor 25 at the lowermost layer. The layer in which insulator 32 is provided corresponds to a layer in which the semiconductor pillar junction MHJT of the NAND string NS is formed. Each of insulators 33 is provided between respective layers of conductors 25-26. Insulator 34 is provided above conductor 26. The layers in which insulators 33 and 34 and conductors 25 and 26 are provided correspond to layers in which the higher layer semiconductor pillar HMH of the NAND string NS is formed.

In the hook-up area A2, conductors 23-26 and insulators 31-34 are formed in a stepwise manner having multiple steps. Conductors 23-26 are provided on an upper surface of each step of the stepwise structure. On the upper surface of each step of the stepwise structure, a non-illustrated contact plug is provided to be electrically coupled to each of conductors 23-26. Through this configuration, each of conductors 23-26 is hooked up via the corresponding contact plug.

In the peripheral area A3, the semiconductor substrate 20 is provided with insulators 36 that function as an element isolating region (STI: Shallow Trench Isolation). Insulator 36 forms, for example, a region which is insulated from p-type well region 22. N-type well region 35 (35_1 and 35_2) is formed on the region isolated from p-type well region 22 of the semiconductor substrate 20. That is to say, p-type well region 22 and n-type well regions 35_1 and 35_2 are formed with insulators 36 interposed therebetween on the semiconductor substrate 20 in the peripheral area A3.

P-type transistors TrP1 and TrP2 are respectively provided on n-type well regions 35_1 and 35_2. Specifically, p-type transistor TrP1 includes p⁺-type impurity diffusion regions 37_1 provided on n-type well region 35_1, and stacked body BYP1 provided above n-type well region 35_1 in an area interposed between p⁺-type impurity diffusion regions 37_1. Similarly, p-type transistor TrP2 includes p⁺-type impurity diffusion regions 37_2 provided on n-type well region 35_2, and stacked body BYP2 provided above n-type well region 35_2 in an area interposed between p⁺-type impurity diffusion regions 37_2. Each of p⁺-type impurity diffusion regions 37_1 and 37_2 functions as a source or a drain of p-type transistors TrP1 and TrP2. Each of stacked bodies BYP1 and BYP2 functions as a gate of p-type transistors TrP1 and TrP2. Contact plugs 39_1 and 39_2 are respectively provided above each of stacked bodies BYP1 and BYP2 so as to reach the gates of p-type transistors TrP1 and TrP2. Contact plugs 39_1 and 39_2 include, for example, tungsten (W).

Contact plug 39_1 includes a lower layer contact plug LCSP1, a higher layer contact plug HCSP1, and a contact plug junction CSJTP1. Lower layer contact plug LCSP1 and higher layer contact plug HCSP1 are placed at a lower position of contact plug junction CSJTP1 and at a higher position of contact plug junction CSJTP1, respectively. Specifically, lower layer contact plug LCSP1 is provided on a lower surface of contact plug junction CSJTP1 to reach the upper surface of p-type transistor TrP1. Higher layer contact plug HCSP1 is provided from the layer in which insulator 34 is provided to reach an upper surface of contact plug junction CSJTP1. Contact plug junction CSJTP1 is provided on the same layer as the layer where insulator 32 is provided, similar to the semiconductor pillar junction MHJT, for example.

On a junction surface between contact plug junction CSJTP1 and lower layer contact plug LCSP1, the diameter (area) of the lower surface of contact plug junction CSJTP1 is greater than the diameter (area) of an upper surface of lower layer contact plug LCSP1. On a junction surface between contact plug junction CSJTP1 and higher layer contact plug HCSP1, the diameter of the upper surface of contact plug junction CSJTP1 is greater than the diameter of a lower surface of higher layer contact plug HCSP1.

Similarly, contact plug 39_2 includes a lower layer contact plug LCSP2, a higher layer contact plug HCSP2, and a contact plug junction CSJTP2. The relationships between lower layer contact plug LCSP2, contact plug junction CSJTP2, and higher layer contact plug HCSP2 in contact plug 39_2 are the same as the relationships between lower layer contact plug LCSP1, contact plug junction CSJTP1, and higher layer contact plug HCSP1 in contact plug 39_1.

N-type transistor TrN is provided on p-type well region 22. Specifically, n-type transistor TrN includes n⁺-type impurity diffusion regions 38 provided on p-type well region 22, and stacked body BYN provided above p-type well region 22 in an area interposed between n⁺-type impurity diffusion regions 38. N⁺-type impurity diffusion regions 38 function as a source or drain of n-type transistor TrN. Stacked body BYN functions as a gate of n-type transistor TrN. Contact plug 40 is provided above stacked body BYN so as to reach the gate of the n-type transistor TrN. Contact plug 40 includes, for example, tungsten (W).

Contact plug 40 includes a lower layer contact plug LCSN, a higher layer contact plug HCSN, and a contact plug junction CSJTN. Lower layer contact plug LCSN and higher layer contact plug HCSN are placed at a lower position of the contact plug junction CSJTN and at a higher position of contact plug junction CSJTN, respectively. Specifically, lower layer contact plug LCSN is provided on a lower surface of contact plug junction CSJTN to reach the upper surface of n-type transistor TrN. Higher layer contact plug HCSN is provided from the layer in which insulator 34 is provided to reach an upper surface of contact plug junction CSJTN. Contact plug junction CSJTN is provided on the same layer as the layer where insulator 32 is provided, similar to the semiconductor pillar junction MHJT, for example.

On a junction surface between contact plug junction CSJTN and lower layer contact plug LCSN, the diameter of the lower surface of contact plug junction CSJTN is greater than the diameter of an upper surface of lower layer contact plug LCSN. On a junction surface between contact plug junction CSJTN and higher layer contact plug HCSN, the diameter of the upper surface of contact plug junction CSJTN is greater than the diameter of a lower surface of higher layer contact plug HCSN.

In FIG. 4 and onwards, contact plugs similar to contact plugs 39_1, 39_2, and 40 that may be formed for each of the source, and the drain of p-type transistors TrP1 and TrP2 and n-type transistor TrN are omitted. Namely, a contact plug corresponding to a source and a contact plug corresponding to a drain may include a lower layer contact plug, a higher layer contact plug, and a contact plug junction with which the lower layer contact plug and the higher layer contact plug are joined, similar to contact plugs 39_1, 39_2, and 40.

1.1.5 Configuration of Transistor

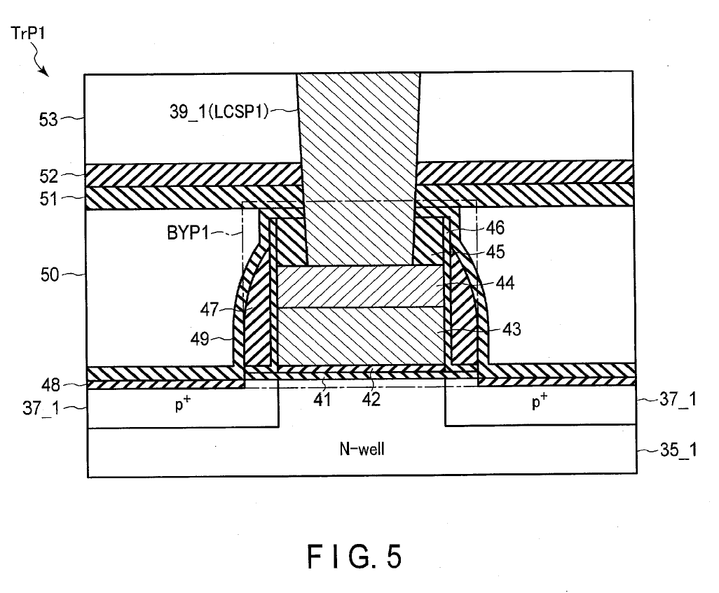

Next, the configuration of the transistors formed in the peripheral area of the semiconductor memory according to the first embodiment will be described with reference to FIGS. 5 to 7. Each of FIGS. 5-7 is a cross-sectional view for explaining the configurations of p-type transistors TrP1 and TrP2 and n-type transistor TrN described with reference to FIG. 4 in detail.

First, the configuration of p-type transistor TrP1 will be described with reference to FIG. 5. P-type transistor TrP1 is, for example, a p-type transistor with a lower breakdown voltage than p-type transistor TrP2. P-type transistor TrP1 is capable of operating with a lower threshold voltage by reducing the EOT (equivalent oxide thickness), which is a thickness of the silicon oxide film equivalent to a thickness of actual gate insulation film, comparing to p-type transistor TrP2.

As shown in FIG. 5, stacked body BYP1 is provided above an area (the channel region of p-type transistor TrP1) interposed between p⁺-type impurity diffusion regions 37_1 in n-type well region 35_1. Stacked body BYP1 includes, for example, oxide 41, nitride 42, conductor 43, conductor 44, nitride 45, oxide 46, and oxide 47. Specifically, on an upper surface of the channel region of p-type transistor TrP1, a film of oxide 41, a film of nitride 42, a film of conductor 43, a film of conductor 44, and a film of nitride 45 among stacked body BYP1 are stacked in the order given.

Oxide 41 functions as a gate insulation film, and includes, for example, silicon dioxide (SiO₂).

Nitride 42 is provided on a part of an upper surface of oxide 41, and includes, for example, silicon nitride (SiN). Nitride 42 functions as a gate insulation film in combination of oxide 41, and functions to prevent the diffusion of p⁺-type impurities doped by conductor 43 in n-type well region 35_1 via oxide 41.

As stated above, in order to activate p-type transistor TrP1 with a small threshold voltage, the total EOT of oxide 41 and nitride 42 is preferably less than 4 nm. A preferable example of the total EOT of oxide 41 and nitride 42 is, for example, approximately 3 nm.

Conductor 43 functions as a gate, and includes, for example, a polysilicon (polycrystalline silicon) in which boron (B) is doped as p⁺-type impurities. Conductor 44 functions as an electrode that is capable of coupling conductor 43 and lower layer contact plug LCSP1 with a low contact resistance, and includes, for example, tungsten silicide (WSi). Namely, conductors 43 and 44 form a polycide structure in which a metal silicide is stacked on a polycrystalline silicon in which a p⁺-type impurity is doped.

Nitride 45 functions as a cap layer, and includes, for example, silicon nitride (SiN).

A film of oxide 46 is formed on a side surface of nitride 42, conductor 43, conductor 44, and nitride 45, and on an upper surface of oxide 41 (except an area in which nitride 42 is provided). In addition, oxide 47 is provided to cover the top of oxide 46. Oxide 46 and oxide 47 function as a sidewall, and include, for example, silicon dioxide (SiO₂).

A film of oxide 48 that functions as a protection film of the semiconductor substrate 20 is formed on upper surfaces of p⁺-type impurity diffusion regions 37_1. Oxide 48 is formed, for example, by performing substrate oxidation to the semiconductor substrate 20, and includes, for example, silicon dioxide (SiO₂).

On an upper surface of nitride 45, oxide 47, and oxide 48, a film of nitride 49 is consecutively formed. Nitride 49 includes, for example, silicon nitride (SiN).

Although hatching is omitted, a film of insulator 50 that functions as an interlayer insulation film is formed on an upper surface of nitride 49 above p⁺-type impurity diffusion region 37_1 to fill a space around stacked body BYP1. Insulator 50 includes, for example, NSG (Non-doped silicate glass).

A film of nitride 51 is formed on an upper surface of insulator 50 and an upper surface of nitride 49 formed on the upper surface of stacked body BYP1.

Nitride 51 includes, for example, silicon nitride (SiN), and functions as a stopper when etching is performed to form contact holes in which contact plugs (not shown in the drawings) electrically coupled with the source and the drain of p-type transistor TrP1, respectively, and lower layer contact plug LCSP1 are provided. A film of oxide 52 is formed on an upper surface of nitride 51. Oxide 52 includes, for example, silicon dioxide (SiO₂).

Although hatching is omitted, a film of insulator 53 that functions as an interlayer insulation film is formed on an upper surface of oxide 52. Insulator 53 includes, for example, dTEOS (silicon oxide formed of TEOS (Tetraethyl ortho-silicate) by plasma CVD (Chemical vapor deposition)).

Lower layer contact plug LCSP1 is provided to penetrate insulator 53, oxide 52, nitride 51, nitride 49, and nitride 45 to reach conductor 44. Lower layer contact plug LCSP1 is in contact with conductor 44, nitride 45, nitride 49, and nitride 51 at a position lower than the layer of oxide 52. Namely, lower layer contact plug LCSP1 is provided not to be in contact with oxide at a position lower than the layer of oxide 52.

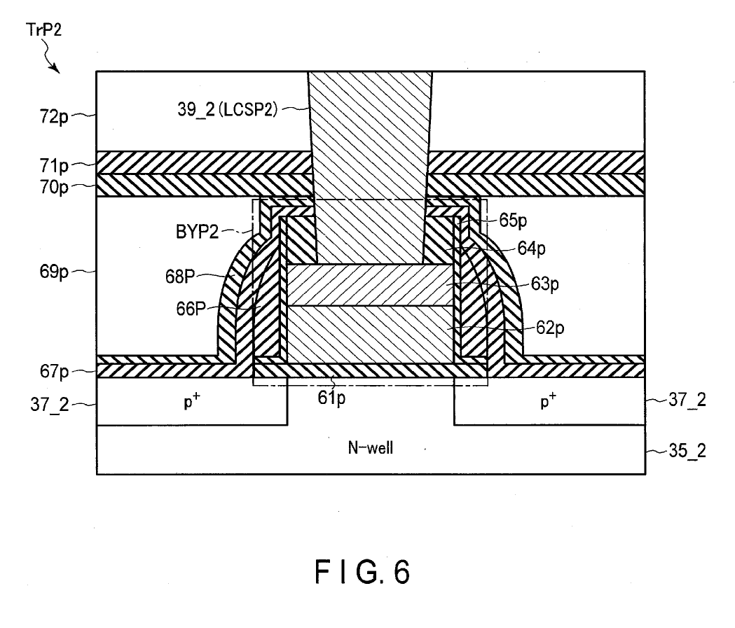

Next, the configuration of p-type transistor TrP2 will be described with reference to FIG. 6. P-type transistor TrP2 is, for example, a p-type transistor with a higher breakdown voltage than p-type transistor TrP1, which is capable of operating with a higher threshold voltage by increasing the EOT of a gate insulation film comparing to p-type transistor TrP1.

As shown in FIG. 6, stacked body BYP2 is provided above an area (the channel region of p-type transistor TrP2) interposed between p⁺-type impurity diffusion regions 37_2 in n-type well region 35_2. Stacked body BYP2 includes, for example, oxide 61p, conductor 62p, conductor 63p, nitride 64p, oxide 65p, and oxide 66p. More specifically, on an upper surface of the channel region of p-type transistor TrP2, a film of oxide 61p, a film of conductor 62p, a film of conductor 63p, and a film of nitride 64p among stacked body BYP2 are stacked in the order given.

Oxide 61p functions as a gate insulation film, and includes, for example, silicon dioxide (SiO₂). As stated above, oxide 61p is formed to have the EOT greater than the total EOT of oxide 41 and nitride 42, to be activated with a greater threshold voltage than p-type transistor TrP1. Specifically, the EOT of oxide 61p is preferably 5 nm or more, for example. A preferable example of the EOT of oxide 61p is, for example, approximately 7 nm.

Conductor 62p functions as a gate, and includes, for example, a polysilicon in which phosphorus (P) is doped as n⁺-type impurities. Conductor 63p functions as an electrode that is capable of coupling conductor 62p and lower layer contact plug LCSP2 with a low contact resistance, and includes, for example, tungsten silicide (WSi). Namely, conductors 62p and 63p form a polycide structure in which metal silicide is stacked on a polycrystalline silicon in which n⁺-type impurities are doped.

Nitride 64p functions as a cap layer, and includes, for example, silicon nitride (SiN).

A film of oxide 65p is formed on a side surface of nitride conductor 62p, conductor 63p, and nitride 64p, and on an upper surface of oxide 61p (except an area in which conductor 62p is provided). In addition, oxide 66p is provided to cover the top of oxide 65p. Oxide 65p and oxide 66p function as a sidewall, and includes, for example, silicon dioxide (SiO₂).

On upper surfaces of p⁺-type impurity diffusion regions 37_2, nitride 64p, and oxide 66p, a film of oxide 67p is consecutively formed. Oxide 67p includes, for example, silicon dioxide (SiO₂).

A film of nitride 68p is formed on an upper surface of oxide 67p. Nitride 68p includes, for example, silicon nitride (SiN).

Although hatching is omitted, a film of insulator 69p that functions as an interlayer insulation film is formed on an upper surface of nitride 68p above p⁺-type impurity diffusion regions 37_2 to fill a space around stacked body BYP2. Insulator 69p includes, for example, NSG.

A film of nitride 70p is formed on an upper surface of insulator 69p and the upper surface of nitride 68p formed above stacked body BYP2. Nitride 70p includes, for example, silicon nitride (SiN), and functions as a stopper when etching is performed to form contact holes in which contact plugs (not shown in the drawings) electrically coupled with the source and the drain of p-type transistor TrP2, respectively, and lower layer contact plug LCSP2 are provided. A film of oxide 71p is formed on an upper surface of nitride 70p. Oxide 71p includes, for example, silicon dioxide (SiO₂).

Although hatching is omitted, a film of insulator 72p is formed on an upper surface of oxide 71p. Insulator 72p includes, for example, dTEOS.

Lower layer contact plug LCSP2 is provided to penetrate insulator 72p, oxide 71p, nitride 70p, nitride 68p, oxide 67p, and nitride 64p to reach conductor 63p. Lower layer contact plug LCSP2 is in contact with conductor 63p, nitride 64p, oxide 67p, nitride 68p, and nitride 70p at a position lower than the layer of oxide 71p. Namely, lower layer contact plug LCSP2 may be in contact with oxide 67p at a position lower than the layer of oxide 71p.

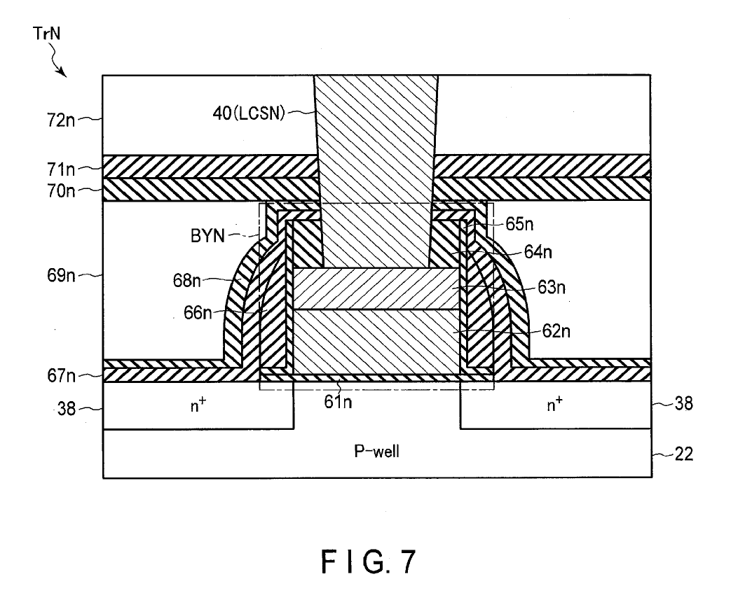

Next, the configuration of n-type transistor TrN will be described with reference to FIG. 7.

In FIG. 7 and onwards, it is assumed that n-type transistor TrN has a gate insulation film of approximately the same EOT as that of p-type transistor TrP1, for convenience; however, the thickness is not limited thereto. N-type transistor TrN according to the embodiment may have a gate insulation film of a gate insulation film of approximately the same EOT as that of p-type transistor TrP1, or may have a gate insulation film of approximately the same EOT as that of p-type transistor TrP2.

As shown in FIG. 7, stacked body BYN is provided above an area (the channel region of n-type transistor TrN) interposed by n⁺-type impurity diffusion regions 38 in P-type well region 22. Stacked body BYN includes, for example, oxide 61n, conductor 62n, conductor 63n, nitride 64n, oxide 65n, and oxide 66n. Specifically, on an upper surface of the channel region of n-type transistor TrN, a film of oxide 61n, a film of conductor 62n, a film of conductor 63n, a film of nitride 64n among stacked body BYN are stacked in the order given. The structure of stacked body BYN is similar to stacked body BYP2 except that the EOT of oxide 61n may differ from the EOT of oxide 61p (may be substantially the same as the total EOT of oxide 41 and nitride 42).

Oxide 61n functions as a gate insulation film, and includes, for example, silicon dioxide (SiO₂). As stated above, n-type transistor TrN may have a similar value of breakdown voltage to p-type transistor TrP1, or may have a similar value of breakdown voltage to p-type transistor TrP2. Accordingly, the EOT of oxide 61n may be less than 4 nm, or may be 5 nm or more. A preferable example of the EOT of oxide 61n is, for example, approximately 3 nm when oxide 61n has a similar value of breakdown voltage to p-type transistor TrP1. A preferable example of the EOT of oxide 61n is, for example, approximately 7 nm when oxide 61n has a value of a breakdown voltage similar to p-type transistor TrP2.

Conductor 62n functions as a gate, and includes, for example, a polysilicon in which phosphorus (P) is doped as n⁺-type impurities. Conductor 63n functions as an electrode that is capable of coupling conductor 62n and lower layer contact plug LCSN with a low contact resistance, and includes, for example, tungsten silicide (WSi). Namely, conductors 62n and 63n form a polycide structure in which metal silicide is stacked on a polycrystalline silicon in which n⁺-type impurities are doped.

Nitride 64n functions as a cap layer, and includes, for example, silicon nitride (SiN).

A film of oxide 65n is formed on a side surface of nitride conductor 62n, conductor 63n, and nitride 64n, and on an upper surface of oxide 61n (except an area in which conductor 62n is provided). In addition, oxide 66n is provided to cover the top of oxide 65n. Oxide 65n and oxide 66n function as a sidewall, and includes, for example, silicon dioxide (SiO₂).

On upper surfaces of the N⁺-type impurity diffusion regions 38, nitride 64n, and oxide 66n, a film of oxide 67n is consecutively formed. Oxide 67n includes, for example, silicon dioxide (SiO₂).

A film of the nitride 68n is formed on an upper surface of the oxide 67n. Nitride 68n includes, for example, silicon nitride (SiN).

Although hatching is omitted, a film of insulator 69n that functions as an interlayer insulation film is formed on an upper surface of nitride 68n above the N⁺-type impurity diffusion regions 38 to fill a space around stacked body BYN. Insulator 69n includes, for example, NSG.

A film of nitride 70n is formed on an upper surface of insulator 69n and an upper surface of nitride 68n formed above stacked body BYN. Nitride 70n includes, for example, silicon nitride (SiN), and functions as a stopper when etching is performed to form contact holes in which contact plugs (not shown in the drawings) electrically coupled with the source and the drain of n-type transistor TrN, respectively, and lower layer contact plug LCSN are provided. A film of oxide 71n is formed on an upper surface of the nitride 70n. Oxide 71n includes, for example, silicon dioxide (SiO₂).

Although hatching is omitted, a film of insulator 72n that functions as an interlayer insulation film is formed on an upper surface of oxide 71n. Insulator 72n includes, for example, dTEOS.

Lower layer contact plug LCSN is provided to penetrate insulator 72n, oxide 71n, nitride 70n, nitride 68n, oxide 67n, and nitride 64n to reach conductor 63n. Lower layer contact plug LCSN is in contact with conductor 63n, nitride 64n, oxide 67n, nitride 68n, and nitride 70n at a position lower than the layer of oxide 71n. Namely, lower layer contact plug LCSN may be in contact with oxide 67n at a position lower than the layer of oxide 71n.

### 1.2 Method of Manufacturing Semiconductor Memory

Next, a manufacturing method of the semiconductor memory according to the first embodiment will be described.

1.2.1 Method of Manufacturing Transistor

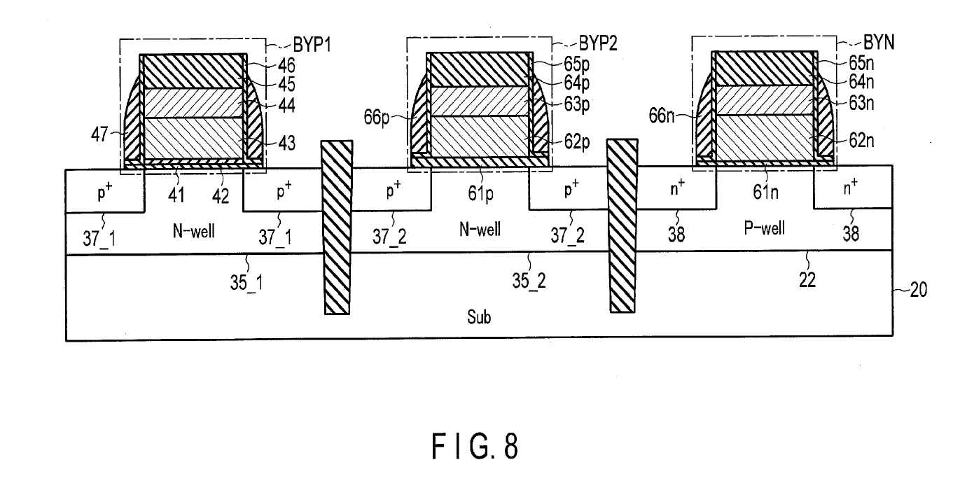

The manufacturing method of the transistor TrP and TrN formed in the peripheral area A3 of the semiconductor memory according to the first embodiment will be described with reference to FIGS. 8 to 13. FIGS. 8 to 13 illustrate the manufacturing method of p-type transistors TrP1 and TrP2, and n-type transistor TrN formed in the peripheral area A3.

As shown in FIG. 8, stacked body BYP1 is formed above n-type well region 35_1, and p⁺-type impurity diffusion regions 37_1 are formed in areas bracketing stacked body BYP1 above n-type well region 35_1. Stacked body BYP2 is formed above n-type well region 35_2, and p⁺-type impurity diffusion regions 37_2 are formed in areas bracketing stacked body BYP2 above n-type well region 35_2. Stacked body BYN is formed above p-type well region 22, and n⁺-type impurity diffusion regions 38 are formed in areas bracketing stacked body BYN above p-type well region 22. The portions of stacked bodies BYP1, BYP2, and BYN having a similar structure and function can be formed in the same process, for example. P⁺-type impurity diffusion regions 37_1 and 37_2 can be formed in the same process.

As stated above, the total EOT of oxide 41 and nitride 42 of stacked body BYP1 is set to be smaller than the EOT of oxide 61p of stacked body BYP2. Stacked body BYP1 is formed to include nitride 42 between oxide 41 and conductor 43; stacked bodies BYP2 and BYN do not include nitride between oxide 61p and conductor 62p, or between oxide 61n and conductor 62n. Boron (B) is doped in conductor 43 of stacked body BYP1, and phosphorus (P) is doped in conductor 62p of stacked body BYP2 and in conductor 62n of stacked body BYN.

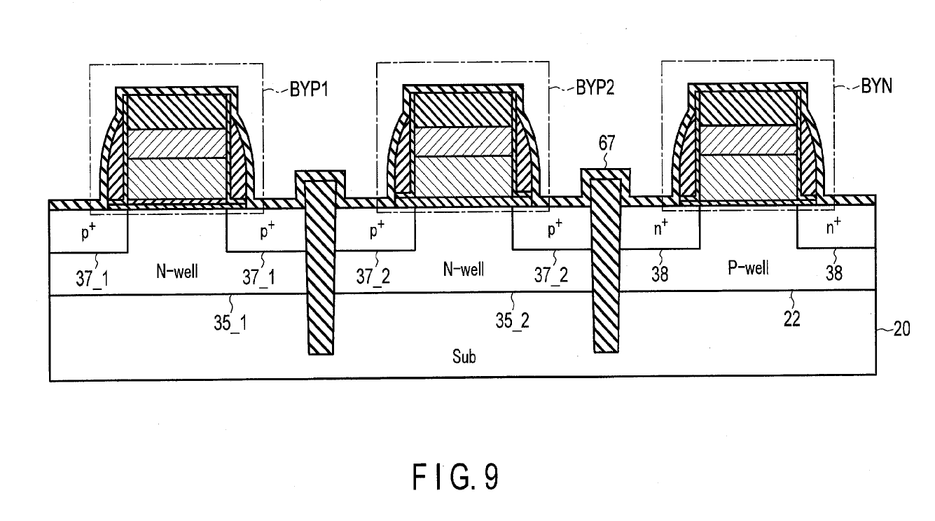

Subsequently, a film of oxide 67 (67p or 67n) is formed on the entire surface of the peripheral area A3, as shown in FIG. 9. Through this process, the upper surfaces of p⁺-type impurity diffusion regions 37_1 and 37_2, n⁺-type impurity diffusion regions 38, and stacked bodies BYP1, BYP2, and BYN are covered by a consecutive film of oxide 67.

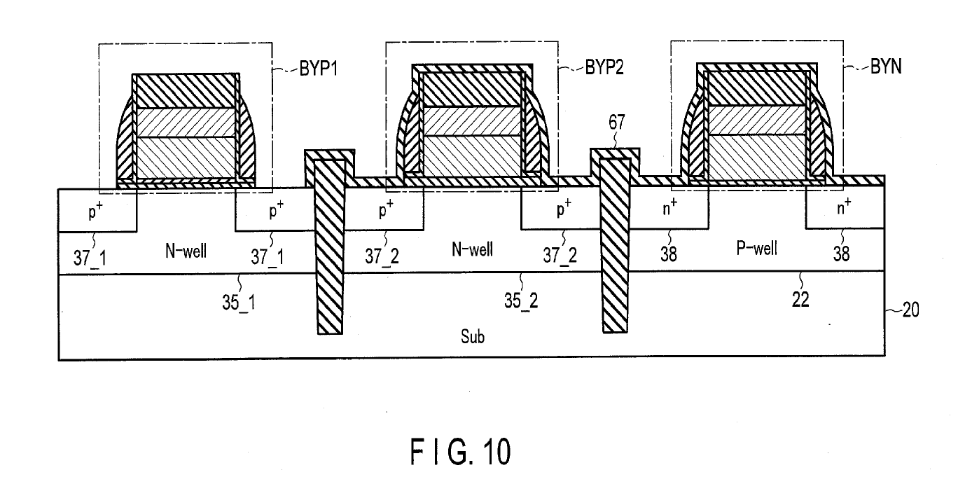

Subsequently, as shown in FIG. 10, wet etching is performed to eliminate portions of oxide 67 which have been provided on p⁺-type impurity diffusion regions 37_1 and stacked body BYP1. When performing wet etching, non-illustrated masks, for example, are provided on the upper surface of oxide 67 provided above p⁺-type impurity diffusion regions 37_2, n⁺-type impurity diffusion regions 38, and stacked bodies BYP2 and BYN. Through this process, the upper surface of p⁺-type impurity diffusion region 37_1 and the side surface and the upper surface of stacked body BYP1 are exposed.

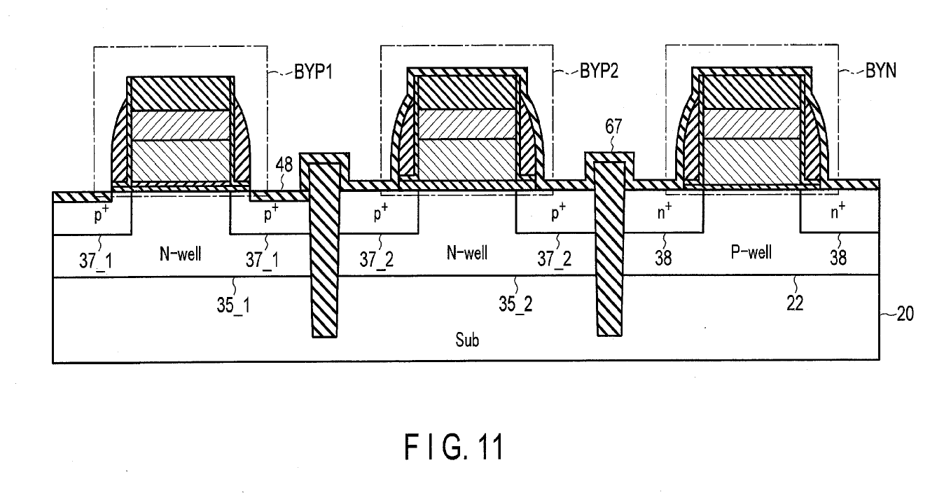

Subsequently, as shown in FIG. 11, by performing thermal processing, for example, the exposed upper portions of p⁺-type impurity diffusion regions 371 are subjected to substrate oxidation. Through this process, a film of oxide 48 is formed on the surface of p⁺-type impurity diffusion regions 37_1. On the other hand, a film of oxide is not newly formed on stacked body BYP1 or oxide 67.

As stated above, oxide 67 is formed on p⁺-type impurity diffusion regions 37_2, and n⁺-type impurity diffusion regions 38; however, oxide 48 is formed by performing oxidation to the upper portions of p⁺-type impurity diffusion regions 37_1. Accordingly, the boundary between p⁺-type impurity diffusion regions 37_1 and oxide 48 is positioned lower than the boundary between oxide 67 and p⁺-type impurity diffusion regions 37_2 or n⁺-type impurity diffusion regions 38.

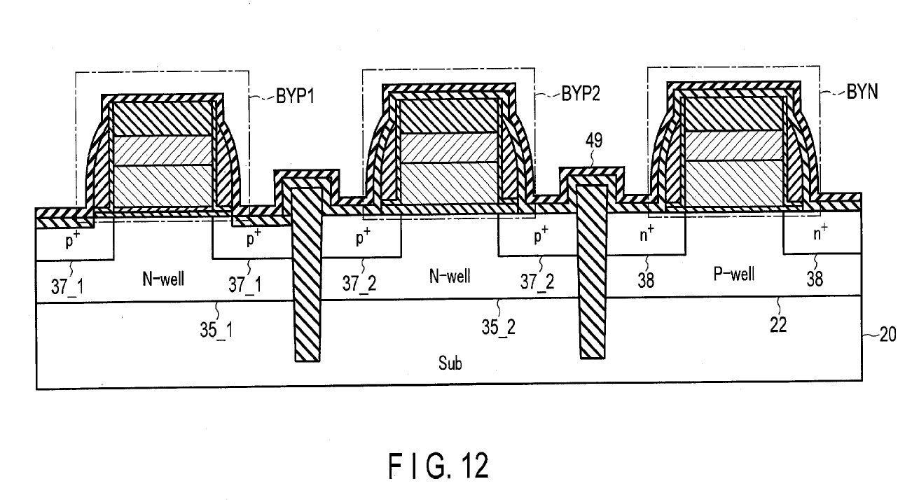

Subsequently, as shown in FIG. 12, nitride 49 (or 68p or 68n) is consecutively formed on the oxide 48, stacked body BYP1, and oxide 67. Through this process, the peripheral area A3 is covered by a consecutive film of nitride 49.

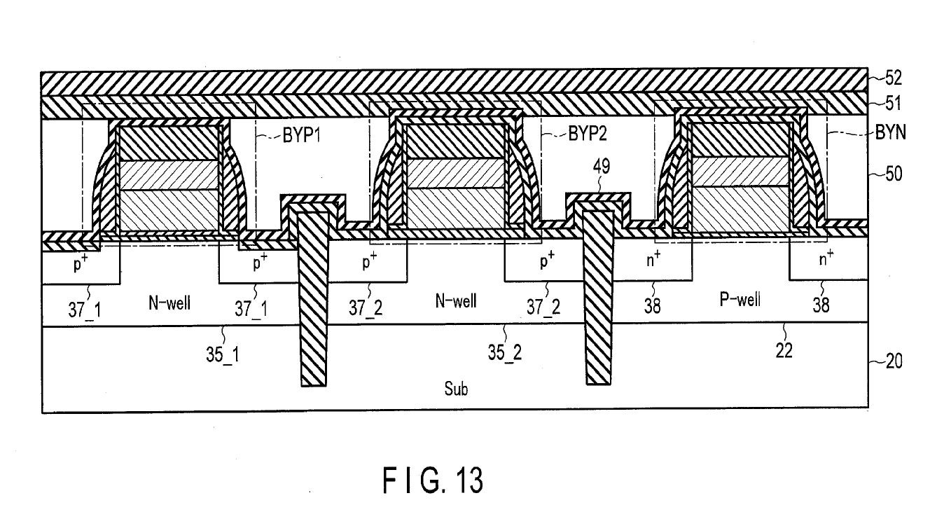

Subsequently, as shown in FIG. 13, insulator 50 (or 69p or 69n) is provided to a level corresponding to the upper surface of stacked body BYP1, for example, over the entire peripheral area A3. Through this process, the upper surfaces of stacked bodies BYP1, BYP2 and BYN are exposed, while the side surfaces of stacked bodies BYP1, BYP2 and BYN are covered by insulator 50.

A film of nitride 51 (or 70p or 70n) is formed on the upper surface of insulator 50, and on the upper surface of nitride 49 (except an area where insulator 50 is provided). Oxide 52 (or 71p or 71n) is provided on the upper surface of nitride 51.

Through the above process, the structures of p-type transistors TrP1 and TrP2, and n-type transistor TrN shown in FIGS. 5-7 immediately before contact plugs 39_1, 39_2, and 40 are formed, are formed in the peripheral area A3.

1.2.2 Method of Manufacturing Contact Plug

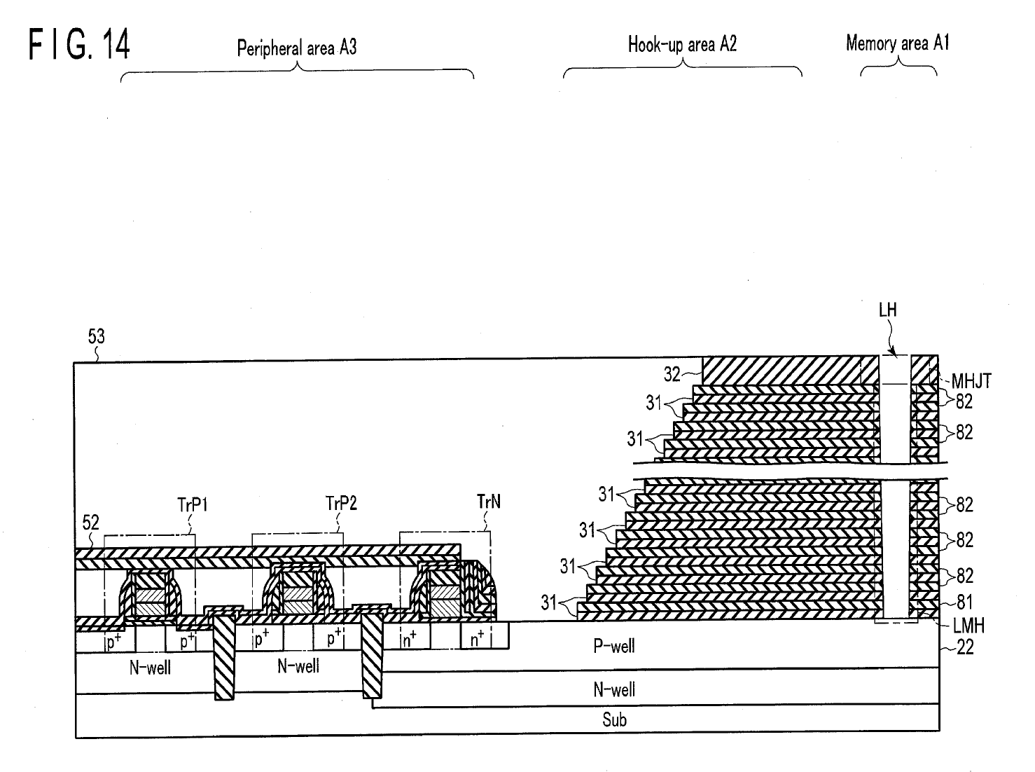

The manufacturing method of a contact plug coupled to a gate of a transistor formed in the peripheral area of the semiconductor memory according to the first embodiment will be described with reference to FIGS. 14 through 24.

FIGS. 14 through 24 illustrate the process where contact plugs 39_1, 39_2, and 40 that function as contact plugs are coupled respectively to the gates of p-type transistors TrP1 and TrP2 and n-type transistor TrN.

As shown in FIG. 14, p-type transistors TrP1 and TrP2 and n-type transistor TrN described with reference to FIGS. 8-13 are formed in the peripheral area A3. In the memory area A1 and the hook-up area A2, a structure of the stepwise stacked body up to the level where the lower layer semiconductor pillar LMH and the semiconductor pillar junction MHJT are to be formed in the semiconductor pillar MH (hereinafter also referred to as “lower side stacked structure”) is formed.

Specifically, insulator 31 and replacement material 81 or 82 are alternately stacked on p-type well region 22 in the memory area A1 and the hook-up area A2. More specifically, replacement material 81 is provided on the upper surface of insulator 31 at the lowermost layer, and insulator 31 and replacement material 82 are alternately stacked on the replacement material 81. Replacement materials 81 and 82 include, for example, silicon nitride (SiN). Insulator 32 is provided above the replacement material 82 at the uppermost layer. In the hook-up area A2, the stacked body including insulators 31 and 32 and replacement materials 81 and 82 is formed in a stepwise manner so that replacement material 81 or 82 is placed on the upper surface of each step. Specifically, a non-illustrated mask is provided on the upper surface of insulator 32 over the memory area A1, the hook-up area A2, and the peripheral area A3. Subsequently, after a pattern is formed in the mask by lithography, anisotropic etching of the lower side stacked structure is performed based on the obtained pattern, and slimming of the mask pattern is performed to eliminate a part of the mask pattern. The processes are repeated sequentially. Through these processes, etching can be performed to make the lower side stacked structure to be stepwise. Thereafter, insulator 53 (or 72p or 72n) is provided on oxide 52, up to the level so that the periphery of the lower side stacked structure is filled (for example, the same layer in which insulator 32 is provided).

In the memory area A1, lower layer memory hole LH is formed in an area of the lower side stacked structure where the lower layer semiconductor pillar LMH and the semiconductor pillar junction MHJT are to be formed.

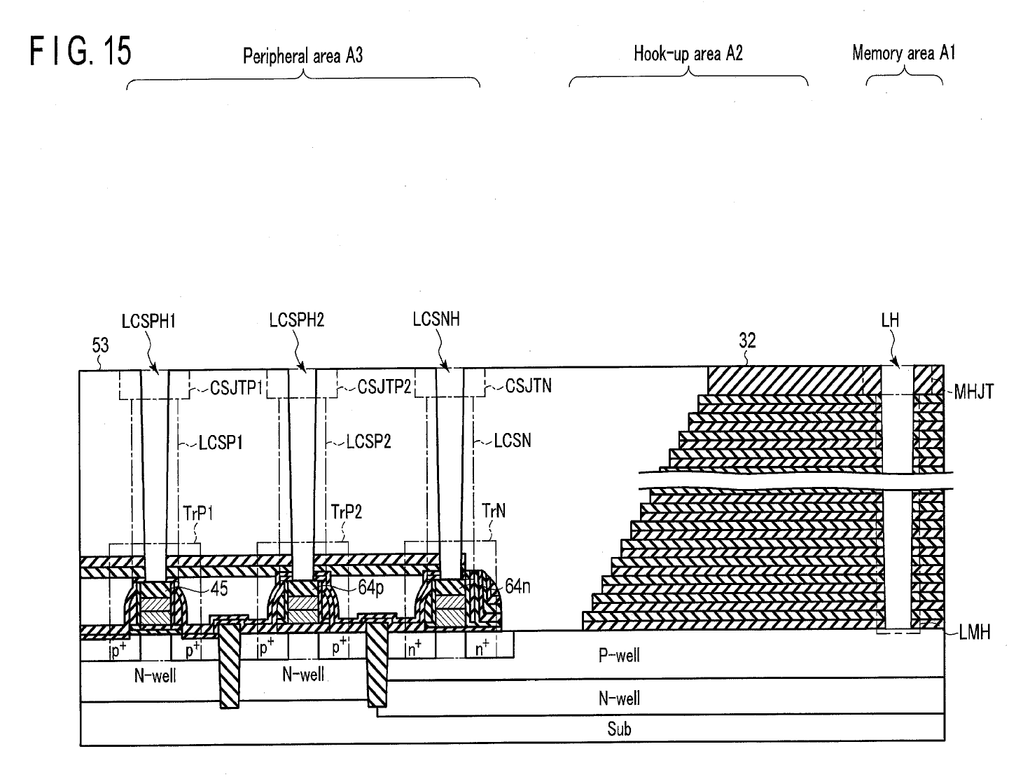

Subsequently, as shown in FIG. 15, in the peripheral area A3, lower layer contact hole LCSPH1 is formed in an area where lower layer contact plug LCSP1 and contact plug junction CSJTP1 are to be provided. Lower layer contact hole LCSPH2 is formed in an area where lower layer contact plug LCSP2 and contact plug junction CSJTP2 are to be provided. Lower layer contact hole LCSNH is formed in an area where lower layer contact plug LCSN and contact plug junction CSJTN are to be provided.

Specifically, when forming lower layer contact holes LCSPH1, LCSPH2, and LCSNH, the lower layer memory hole LH is pre-filled with a non-illustrated mask. Thereafter, a non-illustrated mask, for example, is formed on the upper surfaces of insulators 53 and 32. The parts of mask on insulator 53 is eliminated by lithography, for example, and accordingly, areas where lower layer contact plugs LCSP1, LCSP2, and LCSN are to be provided are exposed. Thereafter, in areas of insulator 53 where the mask is eliminated, lower layer contact holes LCSPH1, LCSPH2, and LCSNH are formed by anisotropic etching by RIE (reactive ion etching). Lower layer contact holes LCSPH1, LCSPH2, and LCSNH penetrate insulator 53 to respectively reach the upper surface of nitride 45 of stacked body BYP1, the upper surface of nitride 64p of stacked body BYP2, and the upper surface of nitride 64n of stacked body BYN. The mask filled in the lower memory hole LH is eliminated as appropriate.

When forming lower layer contact holes LCSPH1, LCSPH2, and LCSNH, lower layer contact holes (not illustrated) to provide contact plugs coupled respectively to sources and drains of p-type transistors TrP1, TrP2, and n-type transistor TrN may be formed at the same time. In this case, in the aforementioned etching process, nitride 51 (or 70p or 70n) functions as a stopper against forming of the lower layer contact holes. Accordingly, when the etching to lower layer contact hole LCSPH1 is performed to reach the upper surface of nitride 45, it is possible to prevent etching to a lower layer contact hole corresponding to a contact plug coupled to each of the source and the drain of p-type transistor TrP1 from reaching to oxide 48.

Thus, in the process described below, when a sacrificial material is filled in the lower layer contact hole corresponding to the contact plug coupled to each of the source and the drain of p-type transistor TrP1, physical coupling between the sacrificial material and nitride 42 through oxide 48 and 41 is prevented.

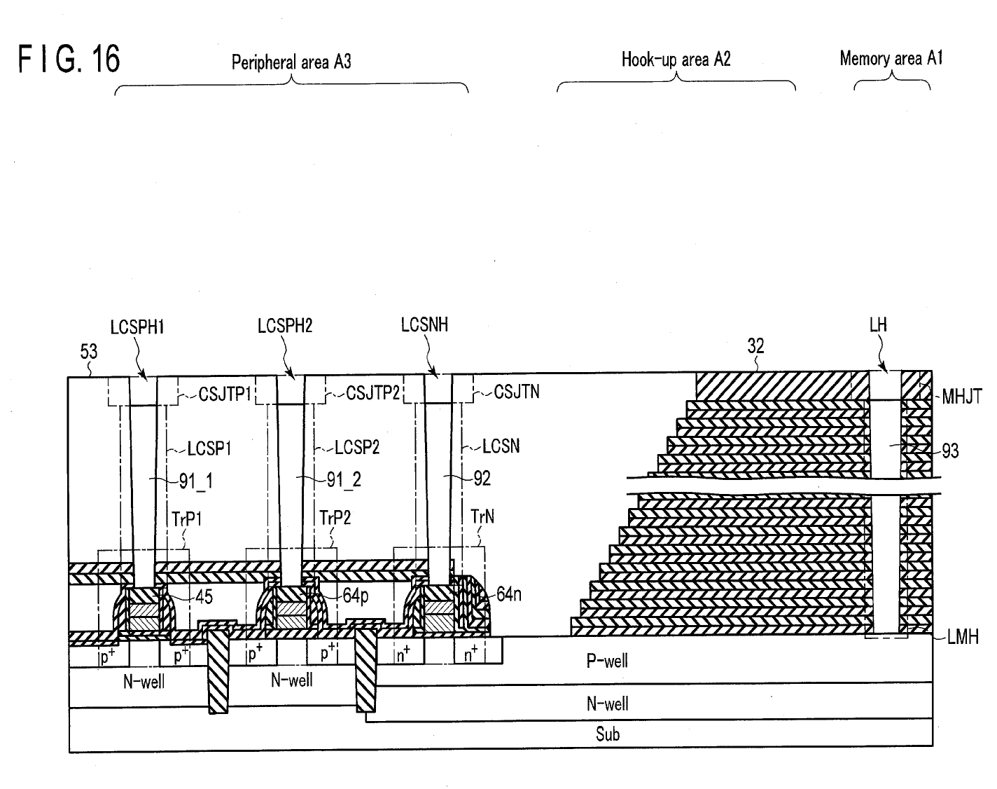

Subsequently, as shown in FIG. 16, sacrificial materials 91_1, 91_2, 92, and 93 are simultaneously filled in respective lower layer contact holes LCSPH1, LCSPH2, LCSNH, and lower layer memory hole LH up to the level where each of lower layer contact plugs LCSP1, LCSP2, LCSN, and lower layer semiconductor pillar LMH is to be formed. Sacrificial materials 91_1, 91_2, 92, and 93 include, for example, amorphous silicon. In the above process, a sacrificial material is simultaneously filled in a lower layer contact hole corresponding to a contact plug coupled to each of the source and the drain of respective transistors.

Specifically, lower layer contact holes LCSPH1, LCSPH2, LCSNH, and lower layer memory hole LH are completely filled with sacrificial materials 91_1, 91_2, 92, and 93, and thereafter, the sacrificial materials 91_1, 91_2, 92, and 93 are etched back to the level where contact plug junctions CSJTP1, CSJTP2, and CSJTN, and semiconductor pillar junction MHJT are to be formed.

Through this process, nitrides 45, 64p, and 64n may be physically coupled with the lower side stacked structure through the sacrificial materials 91_1, 91_2, and 92 (and insulator 53).

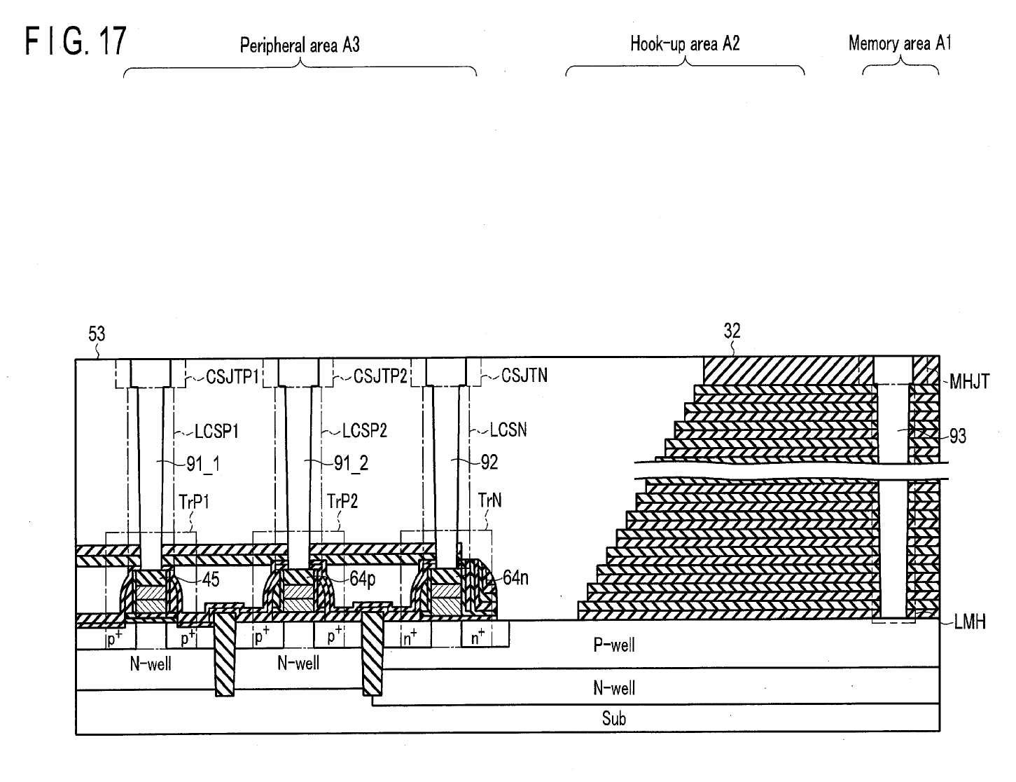

Subsequently, as shown in FIG. 17, the upper portions of lower layer contact holes LCSPH1, LCSPH2, LCSNH, and lower layer memory hole LH are respectively shaped into the shapes of contact plug junctions CSJTP1, CSJTP2, CSJTN, and semiconductor pillar junction MHJT. In the above process, the upper portions of the lower layer contact holes corresponding to contact plugs coupled to each of the source and the drain of respective transistors may be simultaneously shaped into the shape of the contact plug junctions.

Specifically, after a non-illustrated mask is provided on the upper surface of insulators 53 and 32, wet etching that can be selectively eliminate insulators 53 and 32 is performed. Through this process, insulators 53 and 32 are eroded in the horizontal direction from portions exposed by etching back to sacrificial materials 91_1, 91_2, 92, and 93. Accordingly, the diameter of openings of lower layer contact holes LCSPH1, LCSPH2, LCSNH, and lower layer memory hole LH (namely, areas where contact plug junction CSJTP1, CSJTP2, CSJTN and semiconductor pillar junction MHJT are to be formed) is widened.

Thereafter, sacrificial materials 91_1, 91_2, 92, and 93 are respectively filled in the portions in which the shapes of contact plug junctions CSJTP1, CSJTP2, CSJTN, and semiconductor pillar junction MHJT are formed.

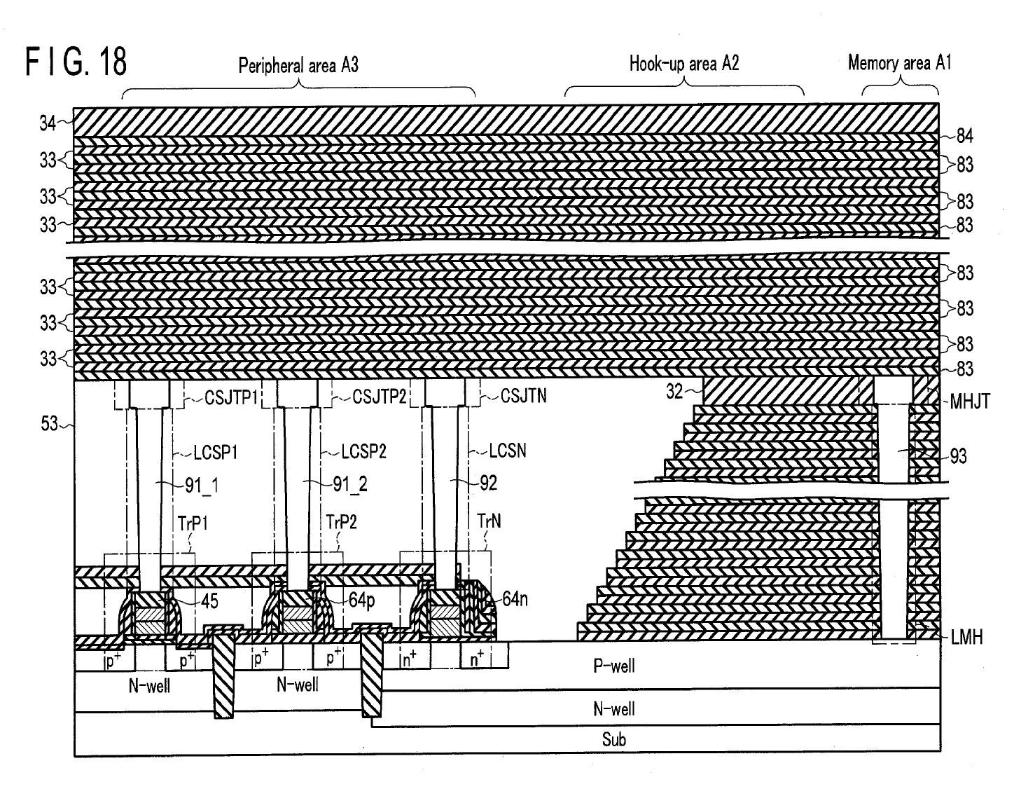

Subsequently, as shown in FIG. 18, a stacked structure of replacement materials 83, and 84 and insulators 33, and (hereinafter also referred to as “upper side stacked structure”) is formed over the memory area A1, the hook-up area A2, and the peripheral area A3. Specifically, replacement material 83 and insulator 33 are alternately stacked on the upper surfaces of insulators 32 and 53 and sacrificial materials 91_1, 91_2, 92, and 93. Replacement material 84 is provided on the upper surface of insulator 33 at the uppermost layer. Insulator 34 is provided on the upper surface of replacement material 84. Replacement materials 83 and 84 include, for example, silicon nitride (SiN).

Namely, p-type transistors TrP1 and TrP2 and n-type transistor TrN can be physically coupled to the upper side stacked structure respectively through sacrificial materials 91_1, 91_2, and 92.

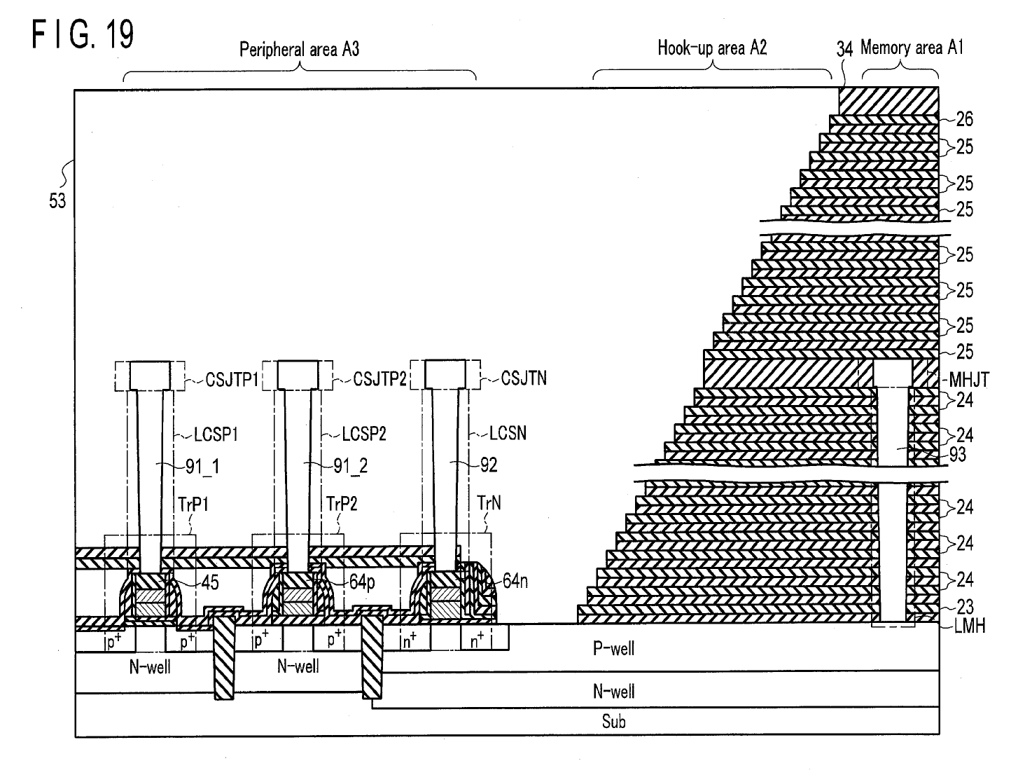

Subsequently, as shown in FIG. 19, the upper side stacked structure is formed in a stepwise manner in the hook-up area A2. Specifically, a non-illustrated mask is provided on the upper surface of insulator 34 over the memory area A1, the hook-up area A2, and the peripheral area A3. Subsequently, after a pattern is formed in the mask by lithography, anisotropic etching of the upper side stacked structure is performed based on the obtained pattern, and slimming of the mask pattern is performed to eliminate a part of the mask pattern. The processes are repeated sequentially. Through these processes, etching can be performed to make the upper side stacked structure to be stepwise. In addition, insulator 53, for example, is filled in the space of the upper side stacked structure which has been eliminated by the anisotropic etching.

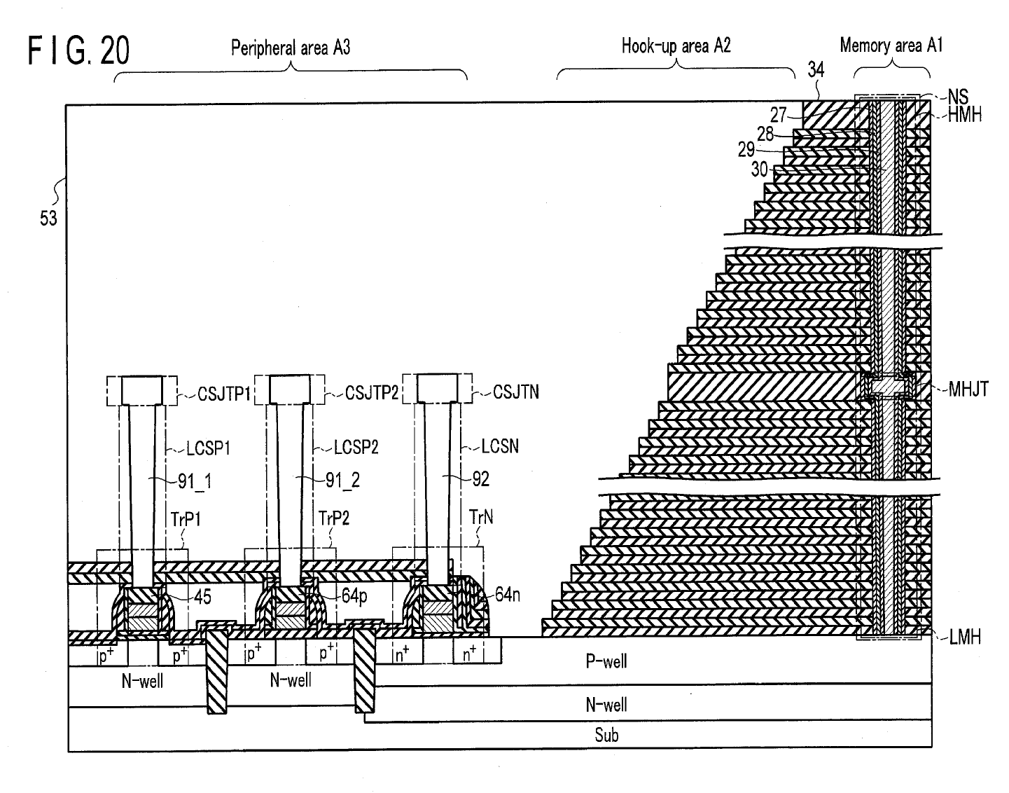

Subsequently, as shown in FIG. 20, an NAND string NS is formed in the memory area A1. Specifically, after a higher layer memory hole is formed by anisotropic etching, and the upper surface of sacrificial material 93 filled up to the semiconductor pillar junction MHJT is exposed, sacrificial material 93 is eliminated by wet etching. Through this process, a memory hole that includes spaces where lower layer semiconductor pillar LMH, semiconductor pillar junction MHJT, and higher layer semiconductor pillar HMH are to be formed. The block insulation film 27 is formed on the inner wall of the memory hole; the insulation film 28 is formed on the inner wall of the block insulation film 27; the tunnel oxide film 29 is formed on the inner wall of the insulation film 28; and the semiconductor film 30 is formed on the internal wall of the tunnel oxide film 29, in the order given.

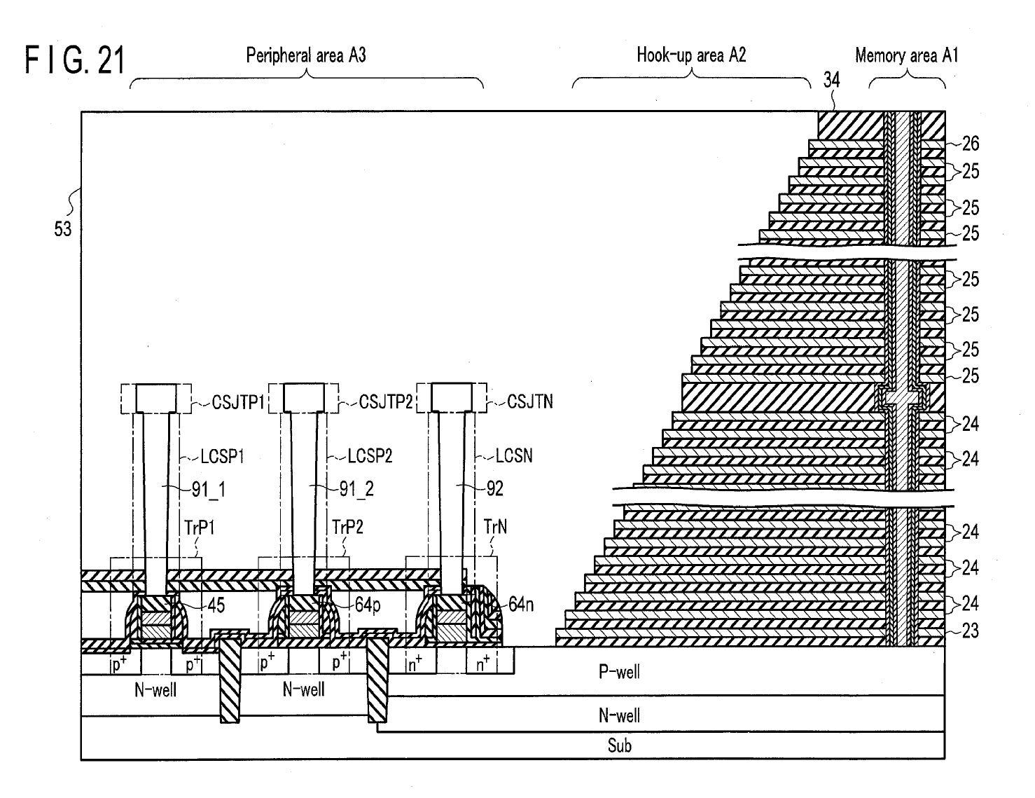

Subsequently, as shown in FIG. 21, replacement materials 81-84 are replaced with conductors 23-26, respectively. As stated above, replacement materials 81-84 are nitride films. Accordingly, they can be simultaneously eliminated by wet etching that allows nitride films to have a greater selectivity than insulators 31-34 which are oxide films. Thereafter, conductors 23-26 are formed in spaces generated by removing the replacement materials 81-84. Conductors 23-26 respectively function as selection gate line SGS, word lines WL0 through WL95, and selection gate line SGD.

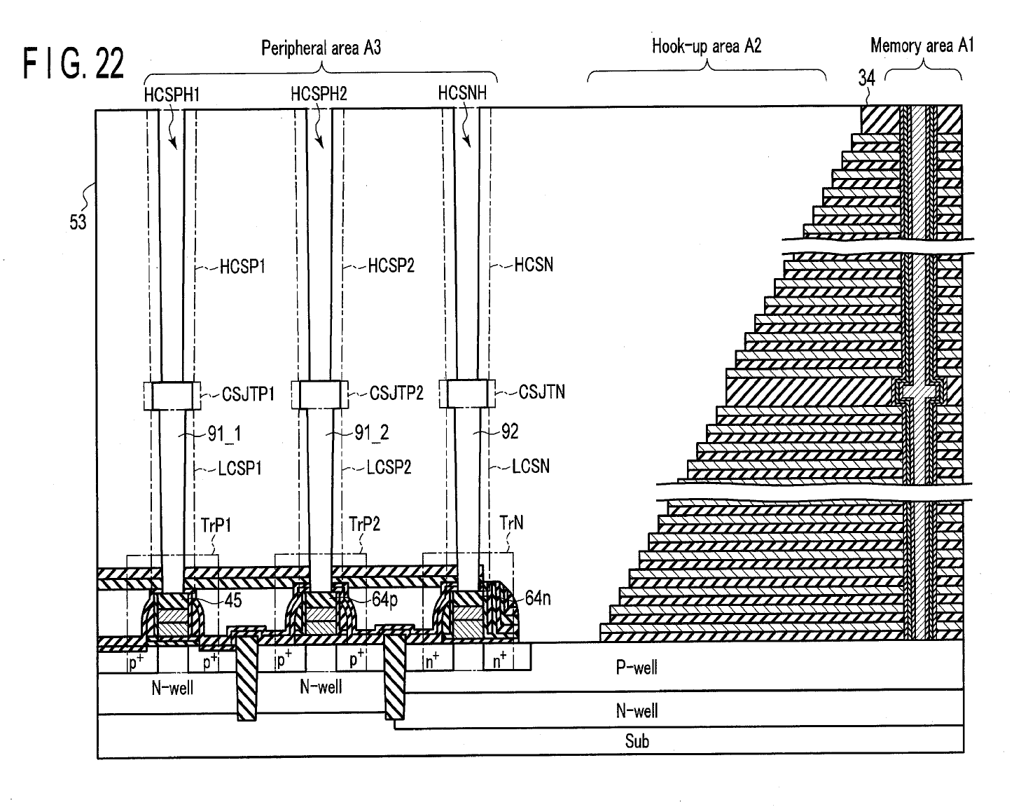

Subsequently, as shown in FIG. 22, higher layer contact holes HCSPH1, HCSPH2, and HCSNH are formed respectively to areas where higher layer contact plugs HCSP1, HCSP2, and HCSN are to be provided. In this process, a higher layer contact hole can be simultaneously formed above a lower layer contact hole corresponding to a contact plug coupled to each of the source and the drain of respective transistors.

Specifically, a non-illustrated mask is provided, for example, by CVD, on the upper surface of insulators 53 and 34 over the memory area A1, the hook-up area A2, and the peripheral area A3. The mask on insulator 53 is eliminated by lithography, for example, and accordingly, areas where higher layer contact plugs HCSP1, HCSP2, and HCSN are to be provided are exposed. Thereafter, in the areas of insulator 53 where the mask is eliminated, higher layer contact holes HCSPH1, HCSPH2, and HCSNH are formed by anisotropic etching by RIE. Each of higher layer contact holes HCSPH1, HCSPH2, and HCSNH reaches the upper surfaces of respective sacrificial materials 91_1, 91_2, and 92.

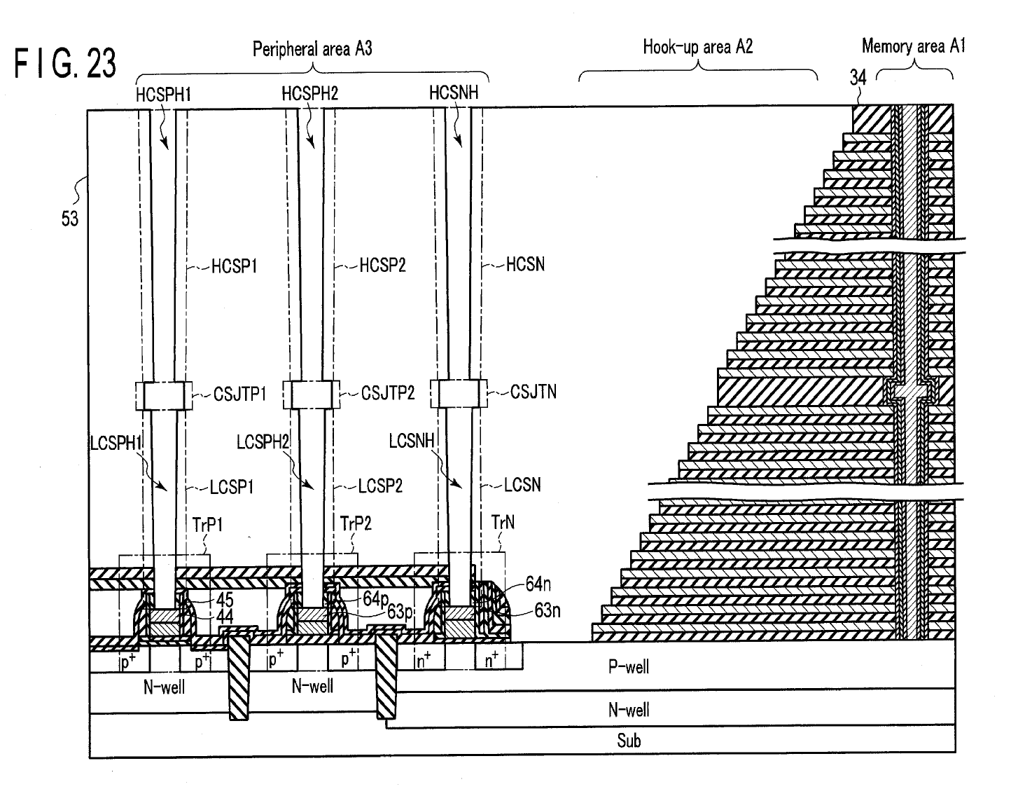

Subsequently, as shown in FIG. 23, sacrificial materials 91_1, 91_2, and 92 are eliminated by wet etching, and lower layer contact holes LCSPH1, LCSPH2, and LCSNH are formed again. Through this process, at the bottom of lower layer contact holes LCSPH1, LCSPH2, and LCSNH, nitride 45 of stacked body BYP1, nitride 64p of stacked body BYP2, and nitride 64n of stacked body BYN are respectively exposed. Each of nitrides 45, 64p, and 64n is eliminated along lower layer contact holes LCSPH1, LCSPH2, and LCSNH by anisotropic etching by RIE. Through this process, at the bottom of lower layer contact holes LCSPH1, LCSPH2, and LCSNH, conductor 44 of stacked body BYP1, conductor 63p of stacked body BYP2, and conductor 63n of stacked body BYN are respectively exposed.

In the above process, the process may be performed to form a lower layer contact hole corresponding to a contact plug coupled to each of the source and the drain of respective transistors, and to expose a diffusion region.

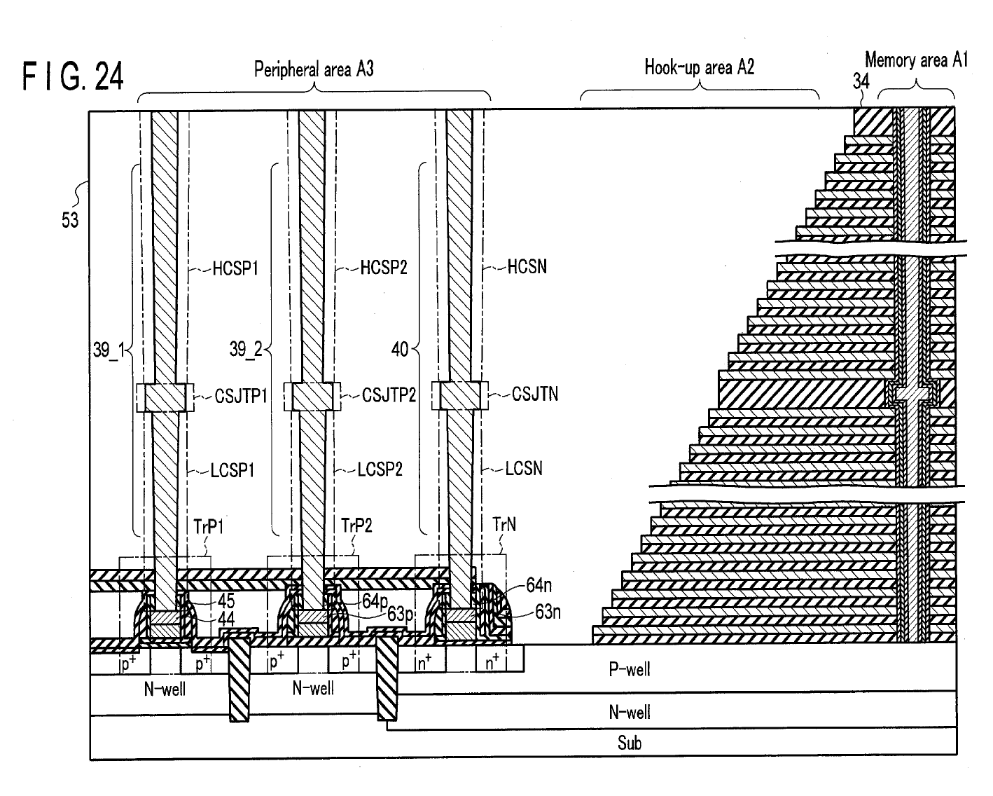

Subsequently, as shown in FIG. 24, contact plug 39_1 is filled in lower layer contact hole LCSPH1 and higher layer contact hole HCSPH1, and contact plug 39_2 is filled in lower layer contact hole LCSPH2 and higher layer contact hole HCSPH2. In addition, contact plug 40 is filled in lower layer contact hole LCSNH and higher layer contact hole HCSNH. In the above process, the process may be simultaneously performed to fill a contact hole corresponding to a contact plug coupled to each of the source and the drain of respective transistors.

Through the aforementioned process, the gate of each of p-type transistors TrP1 and TrP2 and n-type transistor TrN is hooked up through contact plugs 39_1, 39_2, and 40.

### 1.3 Advantageous Effects of Present Embodiment

According to the first embodiment, deterioration of transistor characteristics can be prevented. The advantageous effect will be explained below.

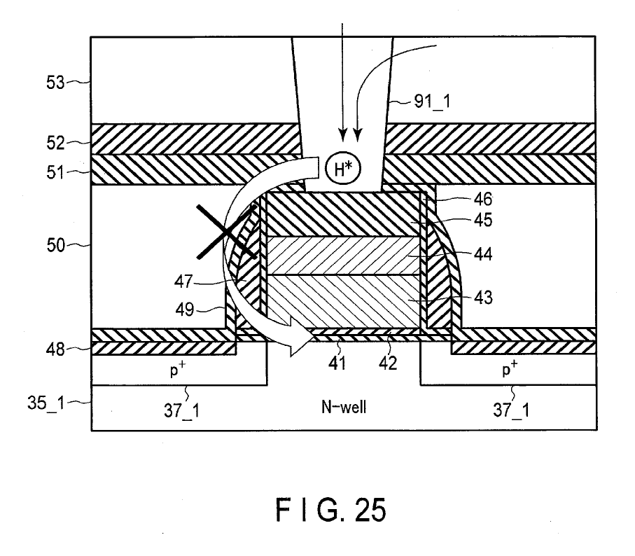

FIG. 25 is a schematic diagram for explaining advantageous effects according to the first embodiment. FIG. 25 illustrates the manufacturing process of the semiconductor memory 1 in which sacrificial material 91_1 is filled in lower layer contact hole LCSPH1 provided above p-type transistor TrP1. FIG. 25 corresponds, for example, to FIG. 18.

As shown in FIG. 25, amorphous silicon used for sacrificial material 91_1, similar to dTEOS used for an insulator, and silicon dioxide (SiO₂) used for oxide, may be a medium that easily propagates hydrogen ion H*. Hydrogen ion H* may be generated inside of replacement materials 81-84 and insulators 31-34 when forming the lower side stacked structure and the upper side stacked structure in the manufacturing process of the semiconductor memory 1.

Hydrogen ion H* can cleave SiN bonds used for nitride. Thus, hydrogen ion H* affects nitride 42 to lower the function of nitride 42 which is to prevent diffusion of boron (B) doped in conductor 43 to n-type well region 35_1. If boron (B) is diffused in n-type well region 35_1, a threshold voltage of p-type transistor TrP1 may vary in an unexpected range, and accordingly, characteristics of p-type transistor TrP1 may be deteriorated. Thus, it is preferable that a path that allows hydrogen ion H* to enter nitride 42 is blocked when manufacturing p-type transistor TrP1.

According to the first embodiment, nitride 49 is provided on the upper surface of nitride 45 of p-type transistor TrP1 without oxide intervention. With this structure, sacrificial material 91_1 is not in contact with oxide physically coupled with nitride 42 at a position lower than the layer of oxide 52. Accordingly, it is possible to prevent hydrogen ion H* propagated to the upper position of p-type transistor TrP1 through sacrificial material 91_1 from reaching nitride 42. Therefore, it is possible to prevent bonds of nitride 42 from being cleaved, and also to prevent the threshold voltage of p-type transistor TrP1 from varying.

A film of oxide 48 is formed on upper portion of p⁺-type impurity diffusion regions 37_1 by substrate oxidation. Through this process, oxide 48 can be provided between p⁺-type impurity diffusion regions 37_1 and nitride 49 without forming a film of oxide on the upper surface of nitride 45. Accordingly, it is possible to prevent crystal defects from being produced in p⁺-type impurity diffusion regions 37_1 due to the stress of nitride 49. Therefore, it is possible to prevent bonds of nitride 42 from being cleaved while protecting p⁺-type impurity diffusion regions 37_1.

A film of oxide 67 is consecutively formed over the peripheral area A3 after stacked bodies BYP1, BYP2, and BYN are formed. Thereafter, oxide 67 is eliminated from the upper surfaces of nitride 45 of stacked body BYP1 and p⁺-type impurity diffusion regions 37_1. Through this process, oxide 67 can be provided for p-type transistor TrP2 and re-type transistor TrN, without the need of substrate oxidation. Accordingly, it is possible to prevent a loss of the upper portion of p⁺-type impurity diffusion regions 37_2 and n⁺-type impurity diffusion regions 38 due to substrate oxidation. Therefore, it is possible to prevent a deterioration in withstand voltage in p-type transistor TrP2 and n-type transistor TrN (especially, for transistors with high breakdown voltage).

As an example of an aspect where sacrificial material 91_1 is filled in contact plug 39_1, the case is assumed where contact plug 39_1 is formed in three steps: firstly in lower layer contact plug LCSP1, secondly in contact plug junction CSJT1, and finally in higher layer contact plug HCSP1.

According to the first embodiment, the stepwise stacked structure is formed step-by-step, i.e., separately in the lower side stacked structure and the upper side stacked structure, in the memory area A1 and the hook-up area A2. Accordingly, the semiconductor pillar MH is formed step-by-step formation of the lower layer semiconductor pillar LMH, the semiconductor pillar junction MHJT, and the higher layer semiconductor pillar HMH. Contact plugs 39_1, 39_2, and 40 are formed in accordance with the formation of the lower layer semiconductor pillar LMH, the semiconductor pillar junction MHJT, and the higher layer semiconductor pillar HMH by step-by-step formation of lower layer contact plugs LCSP1, LCSP2, and LCSN; contact plug junctions CSJTP1, CSJTP2, and CSJTN; and higher layer contact plugs HCSP1, HCSP2, and HCSN.

It is known that characteristics of tungsten (W), used for contact plugs 39_1, 39_2, and 40, are easily deteriorated by being influenced by the manufacturing process of other parts of the semiconductor memory 1. For example, tungsten (W) may easily cause boundary exfoliation of a film by receiving heat due to thermal processing. In addition, tungsten (W) may easily cause corrosion by a chemical solution used for wet etching. According to the first embodiment, after forming lower layer contact holes LCSPH1, LCSPH2, and LCSNH, sacrificial materials 91_1, 91_2, and 92 are respectively filled in lower layer contact holes LCSPH1, LCSPH2, and LCSNH as a replacement of tungsten (W) until higher layer contact holes HCSPH1, HCSPH2, and HCSNH are formed. By using sacrificial materials 91_1, 91_2, and 92, deterioration of contact plugs 39_1, 39_2, and 40 due to various types of processing in the manufacturing method of the semiconductor memory 1 can be prevented.

The process of filling sacrificial materials 91_1, 91_2, and 92 respectively in lower layer contact holes LCSPH1, LCSPH2, and LCSNH is performed simultaneously with the process of filling sacrificial material 93 in the lower layer memory hole LH. The process of forming the shapes of contact plug junctions CSJTP1, CSJTP2 and CSJTN is performed simultaneously with the process of forming the shape of the semiconductor pillar junction MHJT. Accordingly, it is possible to prevent an increase of the processes required for forming contact plugs 39_1, 39_2, and 40.

When forming lower layer contact holes LCSPH1, LCSPH2, and LCSNH, a lower layer contact hole corresponding to a contact plug to be coupled with each of the source and the drain may be simultaneously formed. According to the first embodiment, nitride 51 is formed on the upper surface of nitride 49 and above p⁺-type impurity diffusion regions 37_1. With this structure, when lower layer contact hole LCSPH1 reaches nitride 45 by etching, it is possible to prevent the lower layer contact hole corresponding to the contact plug coupled to each of the source and the drain from reaching oxide 48. Accordingly, it is possible to prevent a possibility that the sacrificial material filled in the lower layer contact hole is coupled to nitride 42 through oxide 48 and 41. Therefore, it is possible to prevent hydrogen ion H* from being propagated to nitride 42 through the sacrificial material filled in the contact plug coupled to each of the source and the drain.

### 2. Second Embodiment

Next, a semiconductor memory according to a second embodiment will be explained. The second embodiment differs from the first embodiment in that a diffusion region of p-type transistors TrP1 and TrP2 and n-type transistor TrN is raised to a higher level relative to the channel region. In the explanation that follows, configurations and manufacturing processes different from those of the first embodiment will be mainly described, and the explanation of similar configurations and manufacturing processes will be omitted.

### 2.1 Configuration of Transistor

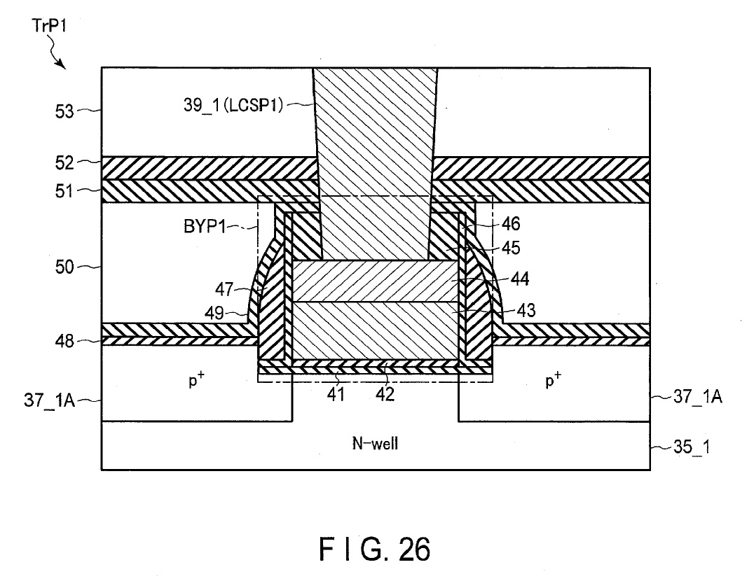

FIG. 26 through FIG. 28 show a cross-sectional view for explaining the detailed configuration of the transistors formed in the peripheral area of the semiconductor memory according to the second embodiment. FIG. 26 through FIG. 28 respectively correspond to FIG. 5 through FIG. 7 explained in the first embodiment.

First, the configuration of p-type transistor TrP1 will be described with reference to FIG. 26.

As shown in FIG. 26, p-type transistor TrP1 according to the second embodiment has p⁺-type impurity diffusion regions 37_1A. The upper surfaces of the p⁺-type impurity diffusion regions 37_1A are placed at a higher level than the lower surface of stacked body BYP1 (namely, the boundary between the channel region of p-type transistor TrP1 and oxide 41). In an example shown in FIG. 26, the upper surfaces of the p⁺-type impurity diffusion regions 37_1A are placed higher than the lower surface of conductor 43 and lower than the upper surface of conductor 43. However, the position is not limited thereto. The upper surfaces of p⁺-type impurity diffusion regions 37_1A may be discretionarily set to a position between the upper surface and the lower surface of stacked body BYP1.

The other configurations such as stacked body BYP1 of p-type transistor TrP1 according to the second embodiment are the same as those of p-type transistor TrP1 according to the first embodiment explained with reference to FIG. 5, and the explanation thereof will be omitted.

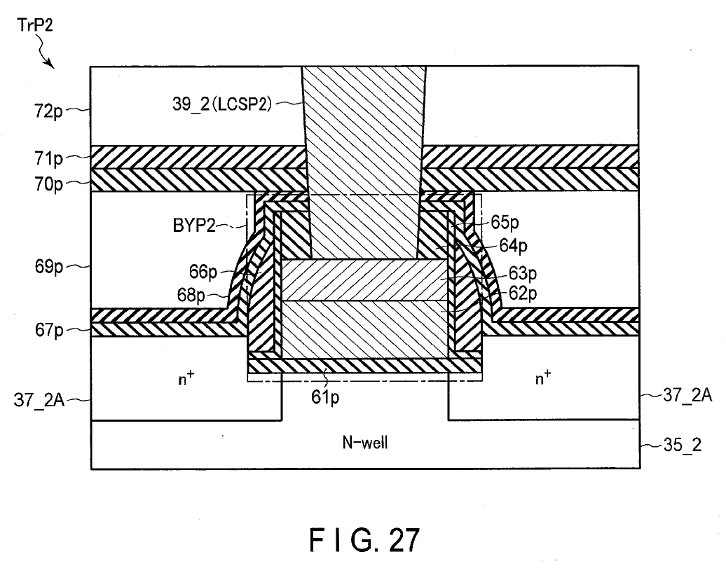

Next, the configuration of p-type transistor TrP2 will be described with reference to FIG. 27.

As shown in FIG. 27, p-type transistor TrP2 according to the second embodiment has p⁺-type impurity diffusion regions 37_2A. The upper surfaces of the p⁺-type impurity diffusion regions 37_2A are placed at a higher level than the lower surface of stacked body BYP2 (namely, the boundary between the channel region of p-type transistor TrP2 and oxide 61p). In an example shown in FIG. 27, the upper surfaces of the p⁺-type impurity diffusion regions 37_2A are placed higher than the lower surface of conductor 62p and lower than the upper surface of conductor 62p. However, the position is not limited thereto. The upper surfaces of p^{#}-type impurity diffusion regions 37_2A may be discretionarily set to a position between the upper surface and the lower surface of stacked body BYP2.

The other configurations such as stacked body BYP2 of p-type transistor TrP2 according to the second embodiment are the same as those of p-type transistor TrP2 according to the first embodiment explained with reference to FIG. 6, and the explanation thereof will be omitted.

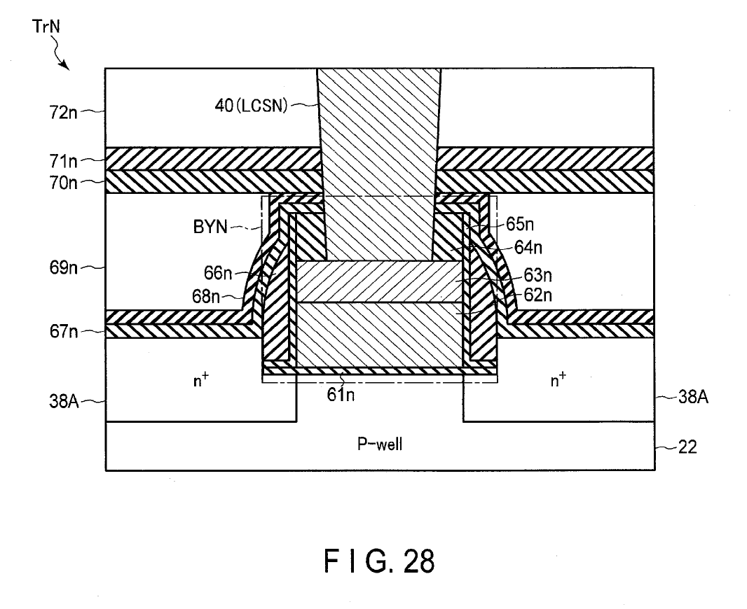

Next, the configuration of n-type transistor TrN will be described with reference to FIG. 28.

As shown in FIG. 28, n-type transistor TrN according to the second embodiment has n⁺-type impurity diffusion regions 38A. The upper surfaces of n⁺-type impurity diffusion regions 38A are placed at a higher level than the lower surface of stacked body BYN (namely, the boundary between the channel region of n-type transistor TrN and oxide 61n). In an example shown in FIG. 28, the upper surfaces of the n^{#}-type impurity diffusion regions 38A are placed higher than the lower surface of conductor 62n and lower than the upper surface of conductor 62n. However, the position is not limited thereto. The upper surfaces of n⁺-type impurity diffusion regions 38A may be discretionarily set to a position between the upper surface and the lower surface of stacked body BYN.

The other configurations such as stacked body BYN of n-type transistor TrN according to the second embodiment are the same as those of n-type transistor TrN according to the first embodiment explained with reference to FIG. 7, and the explanation thereof will be omitted.

### 2.2 Method of Manufacturing Transistor

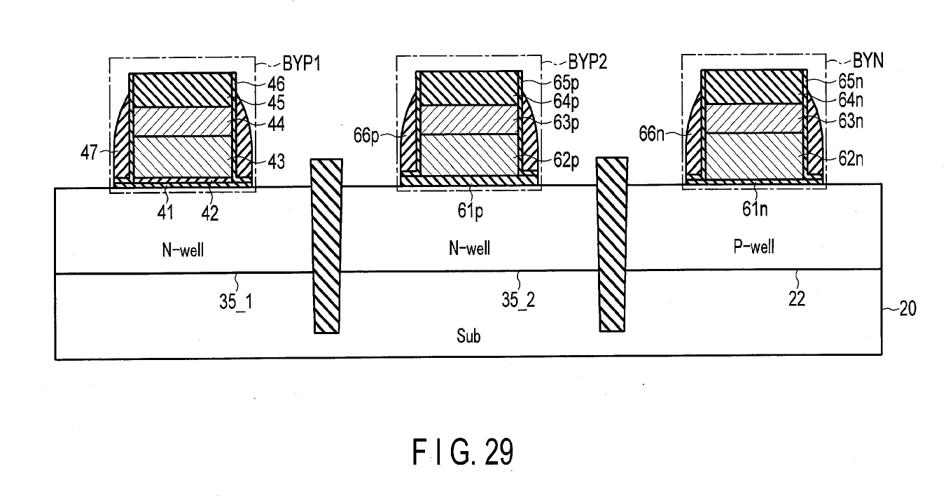

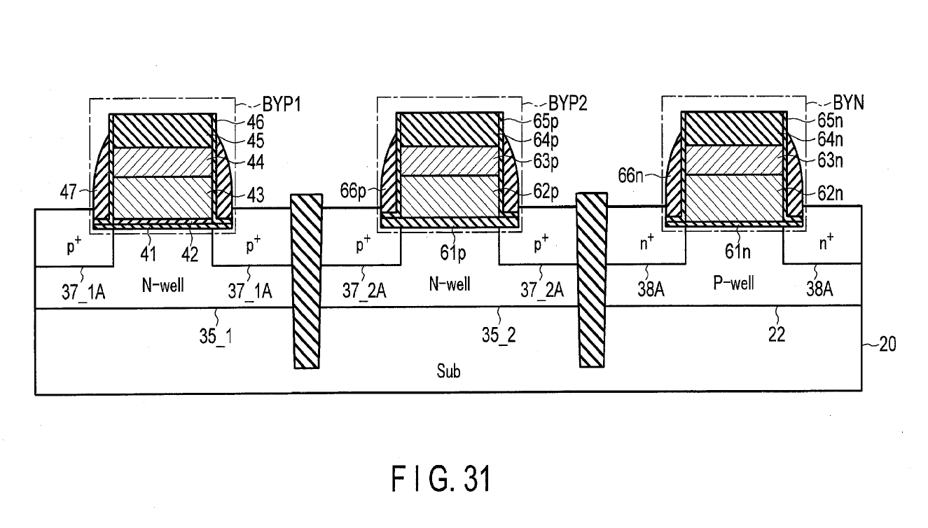

Next, the manufacturing method of transistors formed in the peripheral area of the semiconductor memory according to the second embodiment will be explained with reference to FIGS. 29-36. FIGS. 29 through 36 illustrate the manufacturing process of p-type transistors TrP1 and TrP2, and n-type transistor TrN formed in the peripheral area A3. FIG. 31 through FIG. 36 respectively correspond to FIG. 8 through FIG. 13 explained in the first embodiment.

First, as shown in FIG. 29, stacked body BYP1 is formed above n-type well region 35_1; stacked body BYP2 is formed above n-type well region 35_2; and stacked body BYN is formed above p-type well region 22.

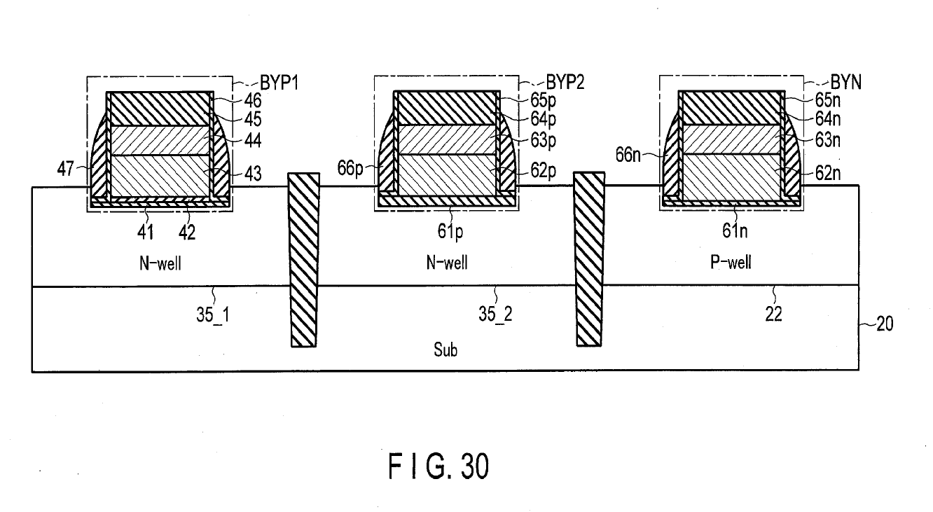

Subsequently, as shown in FIG. 30, areas where p⁺-type impurity diffusion regions 37_1A and 37_2A, and n⁺-type impurity diffusion regions 38A are to be formed are subjected to epitaxial growth. Through this process, areas where diffusion regions of p-type transistors TrP1 and TrP2 and n-type transistor TrN are to be formed are raised relative to the channel region of each transistor.

Subsequently, as shown in FIG. 31, by ion injection of p⁺-type impurities, p⁺-type impurity diffusion regions 37_1A that bracket stacked body BYP1 are formed in two separate areas of the upper portion of n-type well region 35_1, and p⁺-type impurity diffusion regions 37_2A that bracket stacked body BYP2 are formed in two separate areas of the upper portion of n-type well region 35_2. In addition, by ion injection of an n⁺-type impurity, n⁺-type impurity diffusion regions 38A are formed in two separate areas of the upper portion of p-type well region 22 bracketing stacked body BYN.

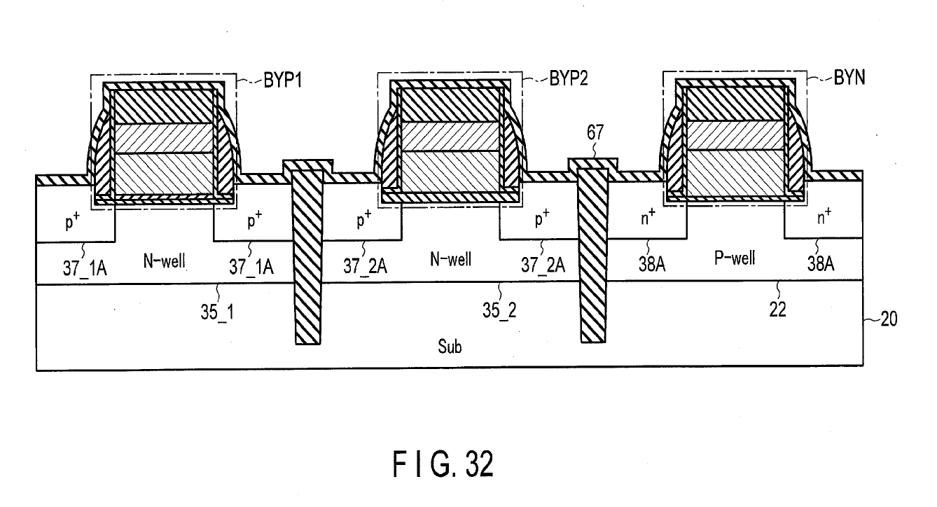

Subsequently, as shown in FIG. 32, a film of oxide 67 is formed on the entire surface of the peripheral area A3. Through this process, the upper surfaces of p⁺-type impurity diffusion regions 37_1A and 37_2A, n⁺-type impurity diffusion regions 38A, and stacked bodies BYP1, BYP2, and BYN are covered by a consecutive film of oxide 67.

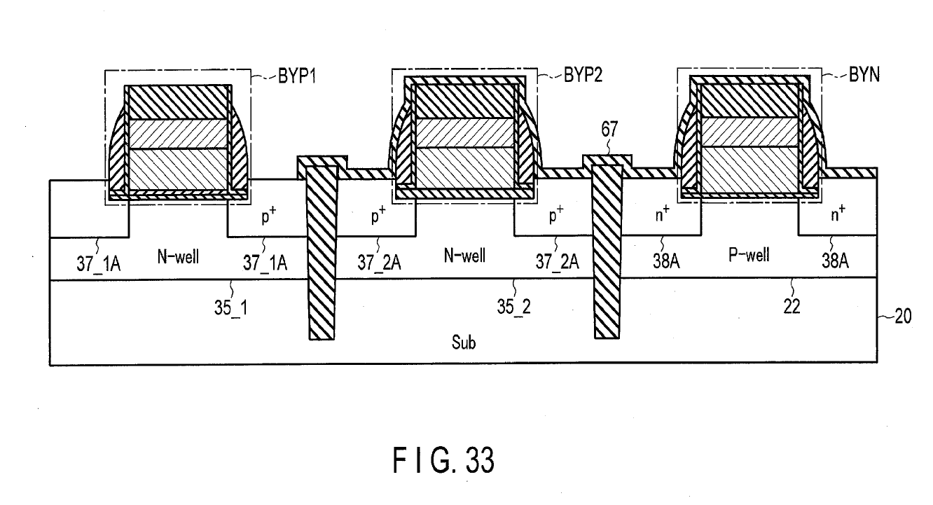

Subsequently, as shown in FIG. 33, of oxide 67, the upper surfaces of p⁺-type impurity diffusion regions 37_1A, the side surface, and the upper surface of stacked body BYP1 are exposed by wet etching.

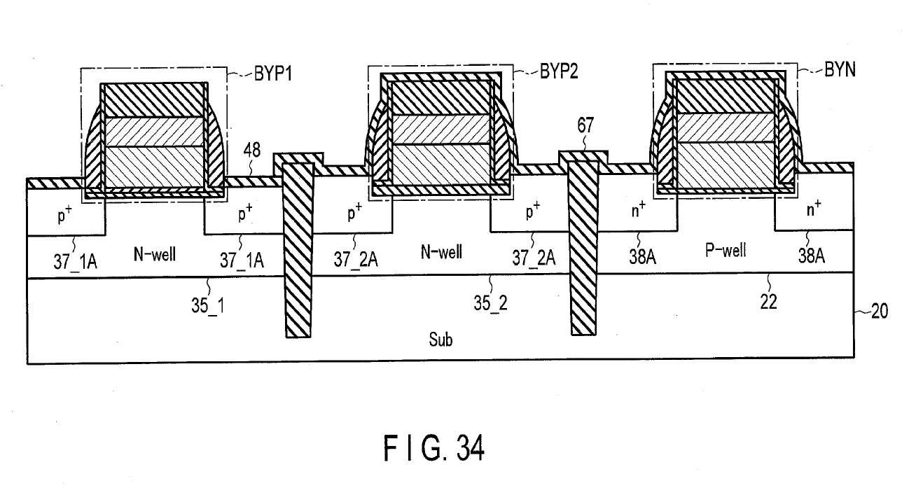

Subsequently, as shown in FIG. 34, substrate oxidation is performed to the upper portions of p⁺-type impurity diffusion regions 37_1A exposed by wet etching. Through this process, a film of oxide 48 is formed on the surface of p⁺-type impurity diffusion regions 37_1A. On the other hand, a film of oxide is not newly formed on stacked body BYP1 or oxide 67.

As stated above, oxide 67 is formed above p⁺-type impurity diffusion regions 37_2A, and n⁺-type impurity diffusion regions 38A; however, oxide 48 is formed by performing oxidation to the p⁺-type impurity diffusion regions 37_1A. Accordingly, the boundary between p⁺-type impurity diffusion regions 37_1A and oxide 48 is positioned lower than the boundary between oxide 67 and p⁺-type impurity diffusion regions 37_2A or n⁺-type impurity diffusion regions 38A.

In addition, as stated above, p⁺-type impurity diffusion regions 37_1A are raised by epitaxial growth. Accordingly, even after the oxide 48 is formed by substrate oxidation, the boundary between p⁺-type impurity diffusion regions 37_1A and oxide 48 can be positioned higher than the boundary between the channel region of p-type transistor TrP1 and oxide 41.

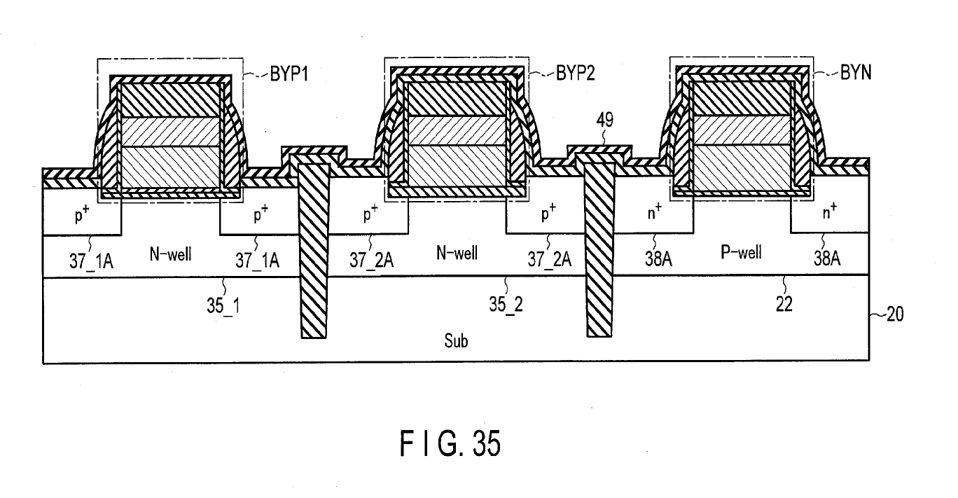

Subsequently, as shown in FIG. 35, nitride 49 is consecutively formed above oxide 48, stacked body BYP1, and oxide 67. Through this process, the peripheral area A3 is covered by a consecutive film of nitride 49.

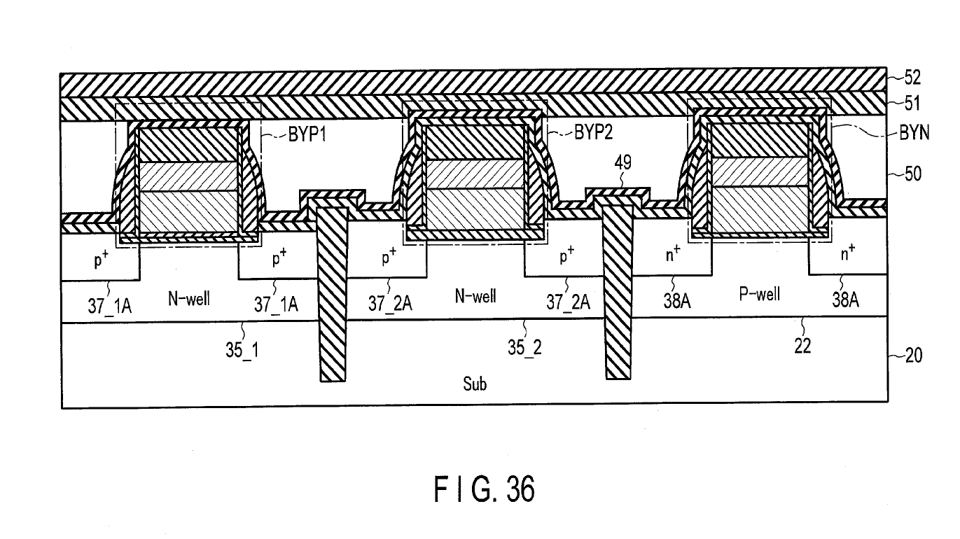

Subsequently, as shown in FIG. 36, insulator 50 is provided to the level corresponding to the upper surface of stacked body BYP1, for example, over the entire peripheral area A3. Through this process, the upper surfaces of stacked bodies BYP1, BYP2, and BYN are exposed, while the side surfaces of stacked bodies BYP1, BYP2, and BYN are covered by insulator 50.

A film of nitride 51 is formed on the upper surface of insulator 50 and the upper surface of nitride 49. Oxide 52 is provided on the upper surface of nitride 51.

Through the above process, the structures of p-type transistors TrP1 and TrP2, and n-type transistor TrN shown in FIGS. 26-28 immediately before contact plugs 39_1, 39_2, and 40 are formed are formed in the peripheral area A3.

### 2.3 Advantageous Effects of Present Embodiment

According to the second embodiment, areas where p⁺-type impurity diffusion regions 37_1A and 37_2A, and n⁺-type impurity diffusion regions 38A are to be formed are raised by epitaxial growth. Through this process, the boundary between p⁺-type impurity diffusion regions 37_1A and oxide 48 is positioned higher than the boundary between oxide 41 and n-type well regions 35_1. Accordingly, the amount of the diffusion region of p-type transistor TrP1 reduced by substrate oxidation can be compensated by the amount built up by epitaxial growth. Therefore, the sufficient thickness of p⁺-type impurity diffusion regions 37_1A is ensured, and deterioration of the characteristics of p-type transistor TrP1 can be prevented.

### 3. Others

The above-described first and second embodiments can be modified as in the following, for example.

In the first and second embodiments, the semiconductor memory 1 has the structure where memory cell transistors MT having charge storage layers are three-dimensionally arranged, but the structure is not limited thereto. The configurations and manufacturing process regarding the hook-up area A2 and the peripheral area A3 explained in the above embodiments can be adopted in other semiconductor memory devices. For example, the configurations and manufacturing process regarding the hook-up area A2 and the peripheral area A3 explained in the above embodiments may be adopted to semiconductor memory devices having the structure where phase change memory cells are three-dimensionally arranged, or to semiconductor memory devices having the structure where memory cells using ferroelectric thin film materials are three-dimensionally arranged.

In addition, in the above embodiments, the method for manufacturing the memory area A1 includes alternately stacking insulator 31 or 32 and replacement 81 or 82 including silicon nitride (SiN) on the p-type well region 22 to form a first stacked body, alternately stacking insulator 33 or 34 and replacement 83 or 84 including silicon nitride (SiN) to form a second stacked body above the first stacked body, and replacing the replacements 81, 82, 83, and 84 with conductors 23, 24, 25, and 26, but the method is not limited thereto. For example, material including a metal or silicon etc. may be used instead of silicon nitride (SiN) to form a stacked structure of conductive materials and insulators 31-34 on the p-type well region 22, and the conductive materials of the stacked structure may function as selection gate line SGS, SGD, and word lines WL0 through WL95, without replacing the conductive materials to other materials.

While certain embodiments have been described, these embodiments have been presented by way of example only, and are not intended to limit the scope of the embodiments. Indeed, the novel embodiments described herein may be embodied in a variety of other forms; furthermore, various omissions, substitutions and changes in the form of the embodiments described herein may be made without departing from the spirit of the invention. The accompanying claims and their equivalents are intended to cover such forms or modifications as would fall within the scope and spirit of the invention.

What is claimed is:

1. A semiconductor device comprising:
a first transistor that includes:
a first stacked body in which a first oxide, a first nitride, a first conductor, and a second nitride are subsequently stacked above a substrate; and
first diffusion regions that are provided on the substrate and bracket the first stacked body; and
a second transistor that includes:
a second stacked body in which a second oxide, a second conductor, and a third nitride are subsequently stacked above the substrate; and
second diffusion regions that are provided on the substrate and bracket the second stacked body,
wherein the first transistor further includes a third oxide provided on the first diffusion regions, and a fourth nitride consecutively provided on the third oxide and the second nitride, and
wherein the second transistor further includes a fourth oxide consecutively provided on the second diffusion regions and the third nitride, and a fifth nitride provided on the fourth oxide.

2. The device of claim 1, wherein the first conductor includes a polycrystalline silicon in which boron (B) is doped.

3. The device of claim 2, wherein a total equivalent oxide thickness of the first oxide and the first nitride of the first stacked body is smaller than an equivalent oxide thickness of the second oxide of the second stacked body.

4. The device of claim 1, wherein the second conductor includes polycrystalline silicon in which phosphorus (P) is doped.

5. The device of claim 1, wherein a boundary between the first diffusion regions and the third oxide is positioned higher than an upper surface of the substrate below the first stacked body.

6. The device of claim 1, wherein a boundary between the first diffusion regions and the third oxide is positioned lower than a boundary between the second diffusion regions and the fourth oxide.

7. The device of claim 1, further comprising a contact plug provided on the first conductor so as to penetrate the second nitride and the fourth nitride,
wherein the contact plug includes:
a first portion of the contact plug having a lower surface which is in contact with the first conductor;
a second portion of the contact plug provided above the first portion of the contact plug; and
a third portion of the contact plug having a lower surface which is in contact with an upper surface of the first portion of the contact plug and has an area greater than that of the upper surface of the first portion of the contact plug, having an upper surface which is in contact with a lower surface of the second portion of the contact plug and has an area greater than that of the lower surface of the second portion of the contact plug, and electrically coupling the first portion of the contact plug and the second portion of the contact plug.

8. The device of claim 7, further comprising:
a third stacked body in which a third conductor and a first insulator are alternately stacked;
a first portion of a semiconductor film that penetrates the third stacked body in a stacking direction where the third conductor and the first insulator are stacked;
a fourth stacked body in which a fourth conductor and a second insulator are alternately stacked in the stacking direction, and which is positioned above the third stacked body;
a second portion of the semiconductor film that penetrates the fourth stacked body in the stacking direction, and is electrically coupled to the first portion of the semiconductor film; and
a third portion of the semiconductor film that electrically couples the first portion of the semiconductor film and the second portion of the semiconductor film,
wherein the third portion of the semiconductor film has:
a lower surface which is in contact with an upper surface of the first portion of the semiconductor film and has an area greater than that of the upper surface of the first portion of the semiconductor film; and
an upper surface which is in contact with a lower surface of the second portion of the semiconductor film and has an area greater than that of the lower surface of the second portion of the semiconductor film, and
wherein the third portion of the semiconductor film is formed at a level substantially equal to a level of the third portion of the contact plug relative to the stacking direction.

9. The device of claim 8, further comprising:
a first memory cell transistor formed in the first portion of the semiconductor film and including a gate electrically coupled to the third conductor; and
a second memory cell transistor formed in the second portion of the semiconductor film and including a gate electrically coupled to the fourth conductor.

10. The device of claim 1, wherein the fourth nitride and the fifth nitride are consecutively formed.

11. The device of claim 1, further comprising a nitride film formed on a part of the fourth nitride provided on the second nitride and formed above the first diffusion regions.

12. The device of claim 11, further comprising a contact plug that penetrates the second nitride, the fourth nitride and the nitride film, and is in contact with an upper surface of the first conductor.

13. The device of claim 1, wherein the first diffusion regions include p⁺-type impurity diffusion regions.

14. A manufacturing method of a semiconductor device comprising:
forming above a substrate a first stacked body in which a first oxide, a first nitride, a first conductor, and a second nitride are subsequently stacked, forming on the substrate first diffusion regions that bracket the first stacked body, forming above the substrate a second stacked body in which a second oxide, a second conductor, and a third nitride are subsequently stacked, and forming on the substrate second diffusion regions that bracket the second stacked body;
forming a third oxide on the first diffusion regions, and forming a fourth oxide consecutively on the second diffusion regions and the third nitride, wherein the forming the third oxide and the fourth oxide includes providing the fourth oxide consecutively on the first diffusion regions, the second nitride, the second diffusion regions, and the third nitride, eliminating a part of the fourth oxide provided on the first diffusion regions and the second nitride, and forming the third oxide on the first diffusion regions in which the fourth oxide is eliminated; and
providing a nitride film consecutively on the third oxide, the second nitride, and the fourth oxide.

15. The method of claim 14, wherein the forming the third oxide includes oxidizing a surface of the first diffusion regions.

16. The method of claim 14, further comprising performing epitaxial growth to areas of an upper surface of the substrate that correspond at least to the first diffusion regions of the first diffusion regions and the second diffusion regions.

17. The method of claim 14, further comprising:
after providing the nitride film, forming a third stacked body in which a first material and a first insulator are alternately stacked in an area different from an area where the first stacked body and the second stacked body are formed, and forming an insulation film that covers above the nitride film and a side surface of the third stacked body;
forming a memory hole that penetrates the third stacked body in a stacking direction where the first material and the first insulator are stacked, and forming a contact hole that penetrates the insulation film in the stacking direction to reach the second nitride;
forming a first sacrificial material inside the memory hole and a second sacrificial material inside the contact hole; and
after forming the first sacrificial material and the second sacrificial material, forming a fourth stacked body in which a second material and a second insulator are alternately stacked above the third stacked body, and the first sacrificial material.

18. The method of claim 17, further comprising replacing the first material with a third conductor, and replacing the second material with a fourth conductor.

19. The method of claim 17, wherein the first sacrificial material and the second sacrificial material include amorphous silicon.

20. The method of claim 14, wherein the forming the first stacked body includes doping boron (B) in the first conductor, and the forming of the second stacked body includes doping phosphorus (P) in the second conductor.
